(19) United States
(12) Patent Application Publication
(10) Pub. No.: US 2010/0302847 A1
(43) Pub. Date: Dec. 2, 2010

(54) MULTI-LEVEL NAND FLASH MEMORY

(76) Inventors: Hiromitsu Komai, Kamakura-shi (JP); Teruo Takagiwa, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/791,519

(22) Filed: Jun. 1, 2010

(30) Foreign Application Priority Data
Jun. 1, 2009 (JP) 2009-132293

(51) Int. Cl. G11C 16/04; G11C 7/10

(52) U.S. Cl. 365/185.03; 365/189.05; 365/200

(57) ABSTRACT

According to one embodiment, a multi-level NAND flash memory executes a writing of an upper data to a LM flag. When an address of a flag assigns a bad column, a data transfer control circuit and a address control circuit control a write operation of upper data in the flag by an operation of transmitting the upper data of the flag from the bad column data hold circuit to the data latch circuit, reading the lower data of the flag from a redundancy column storing the flag into the data latch circuit, generating an address of a redundancy column storing the flag based on the address of the flag, and forcefully inverting the lower data of the flag in the data latch circuit by using the address of the redundancy column storing the flag.

### CROSS-REFERENCE TO RELATED APPLICATION

This application is based upon and claims the benefit of priority from the prior Japanese Patent Application No. 2009-132293, filed Jun. 1, 2009, the entire contents of which are incorporated herein by reference.

### FIELD

Embodiments described herein relate generally to a data writing technique of a multi-level NAND flash memory.

### BACKGROUND

There has been proposed a writing technique called an LM (Lower Middle) mode to prevent threshold fluctuation due to the parastic capacitance of adjacent cells associated with cell refinement in a 4-level NAND flash memory.

In the LM mode, a memory cell with lower data written has two threshold distributions, e.g., erased state Er (lower data “1”) and writing state (rough writing state) A-lower (lower data “0”).

A memory cell with lower and upper data written has four threshold distributions, e.g., erased state Er (upper data “1” and lower data “1”), and writing states A (upper data “0” and lower data “1”), B (upper data “0” and lower data “0”), and C (upper data “1” and lower data “0”).

The LM mode is characterized in that threshold distribution A-lower is different from any of threshold distributions A, B, and C. Threshold distribution A is implemented by executing write operation in erased state Er (by increasing a threshold), and threshold distributions B and C are obtained by performing write operation in threshold distribution A-lower.

### BRIEF DESCRIPTION OF THE DRAWINGS

FIG. 1 is a diagram showing a multi-level NAND flash memory.

FIG. 2 is a diagram showing a memory cell array.

FIG. 3 is a diagram showing a bad column data hold circuit.

FIG. 4 is a diagram describing a LM mode.

FIG. 5 is a diagram describing a LM flag.

FIG. 6 is a diagram showing a threshold distribution of LM flag.

FIG. 7 is a diagram showing a writing order for writing an upper data in a LM flag.

FIGS. 8 and 9 are diagrams, each showing an example of data transfer of a bad column.

FIG. 10 is a diagram showing a match signal in a bad column data hold circuit.

FIG. 11 is a diagram showing a NAND flash memory of a first embodiment.

FIG. 12 is a diagram showing a main circuit according to a LM-dump.

FIG. 13 is a diagram showing an address control circuit.

FIG. 14 is a diagram showing a writing order for writing an upper data in a LM flag.

FIG. 15 is a diagram showing a NAND flash memory of a second embodiment.

FIG. 16 is a diagram showing a main circuit according to a LM-dump.

FIG. 17 is a diagram showing a writing order for writing an upper data in a LM flag.

FIG. 18 is a diagram showing a NAND flash memory of a third embodiment.

FIG. 19 is a diagram showing a main circuit according to a LM-dump.

FIG. 20 is a diagram showing an address control circuit.

FIG. 21 is a diagram showing a writing order for writing an upper data in a LM flag.

### DETAILED DESCRIPTION

1. Basic Arrangement

In general, according to one embodiment, a multi-level NAND flash memory comprising a memory cell array, a data transfer control circuit arranged on one side of the memory cell array, and configured to control data transfer to the memory cell array, a data latch circuit arranged between the memory cell array and the data transfer control circuit, a bad column data hold circuit configured to temporarily hold data of a bad column in read/write operation, a data buffer serving as an interface for data, an address buffer serving as an interface for an address, a switch circuit configured to transfer data between two of the data buffer, the data latch circuit, and the bad column data hold circuit, and an address control circuit configured to transfer the address to the bad column data hold circuit, and to prohibit, if the address is determined to assign a bad column in the bad column data hold circuit, transfer operation of the address to the data transfer control circuit.

A threshold distribution of a memory cell constituting the memory cell array is set to a first state or a second state in an ascending order of a threshold in a state in which lower data is written, and is set to a third state, a fourth state, a fifth state, or a sixth state in an ascending order of a threshold in a state in which lower data and upper data are written.

The second state is different from the fourth state, the fifth state, and the sixth state.

The memory cell array includes a main area storing main data, a flag area storing a flag for determining whether the main data contains only lower data or both lower data and upper data, and a redundancy area having a redundancy column.

A threshold distribution of the flag is set to the first state in a state in which lower data is written, and is set to the fifth state in a state in which lower data and upper data are written.

When an address of the flag assigns a bad column, the data transfer control circuit and the address control circuit control a write operation of upper data in the flag by an operation of

transmitting the upper data of the flag from the bad column data hold circuit to the data latch circuit,

reading the lower data of the flag from a redundancy column storing the flag into the data latch circuit,

generating an address of a redundancy column storing the flag based on the address of the flag, and

forcefully inverting the lower data of the flag in the data latch circuit by using the address of the redundancy column storing the flag.

In the embodiment, a technique for high-speed write operation by the LM mode is proposed.

The LM mode is characterized in that threshold distribution A-lower is different from any of threshold distributions A, B, and C. Threshold distribution A is implemented by executing write operation in erased state Er (by increasing a threshold), and threshold distributions B and C are obtained by performing write operation in threshold distribution A-lower.

Note that an LM flag is used in the LM mode in order to determine whether a memory cell stores only lower data or both lower and upper data.

It is determined, for example, that if the value of the LM flag is “L”, the memory cell only stores lower data, and if the value of the LM flag is “H”, the memory cell stores both lower and upper data.

To implement the above LM mode, the threshold distribution of the LM flag must be considered.

Assume, for example, that if the LM flag is “L”, it has threshold distribution Er. To write upper data for changing the LM flag to “H”, threshold distribution Er needs to shift to any one of threshold distributions A, B, and C.

In this embodiment, if the LM flag is “H”, the threshold distribution is set to B.

This is because when reading 4-level data, the data is read using Br between threshold distributions A and B as a read potential first and then the value of the lower data is determined. Furthermore, in this case, the value of the LM flag is preferably determined to be “H”.

For threshold distribution C, the value of the LM flag can also be determined to be “H” based on read potential Br. A smaller threshold shift amount from threshold distribution Er is preferred.

Therefore, if the LM flag is “H”, the threshold distribution is set to B.

According to the write principles of 4-level data, although the threshold distribution can shift from Er to A, the threshold distribution cannot, in principle, shift from Er to B.

The threshold distribution, however, can shift from Er to B (to be referred to as LM-dump hereinafter), by assigning the address of the LM flag, and forcefully changing the value of the upper data of the LM flag from “L (=1)” to “H (=0)” when writing the upper bit for the LM flag.

In recent years, there has been proposed a technique of providing, separately from a memory cell array, a bad column data hold circuit for collectively temporarily storing the data of bad columns in order to achieve high-speed read/write operation.

When this technique is adopted, assume that a column storing the LM flag is a bad column. In LM-dump, access to the bad column is prohibited, and the address of the LM flag assigns a data latch circuit in the bad column data hold circuit corresponding to a redundancy column replacing the bad column.

That is, it is impossible to directly access the redundancy column storing the LM flag.

In LM-dump, therefore, all the data of bad columns are transferred from a data latch circuit corresponding to a redundancy area to the data latch circuit in the bad column data hold circuit, the value of the lower data read from the LM flag is forcefully changed in the bad column data hold circuit, and then all the data of the bad columns are transferred again from the data latch circuit in the bad column data hold circuit to the data latch circuit corresponding to the redundancy area.

As described above, to only change the lower data of the LM flag, all the data of the bad columns are transferred between the data latch circuit corresponding to the redundancy area and that in the bad column data hold circuit, thereby making the write time longer.

In the embodiment, to achieve high-speed write operation by the LM mode, if the address of the LM flag assigns a bad column, write operation of the upper data for the LM flag is performed after the following operation. That is, the upper data of the LM flag is transferred from the bad column data hold circuit to the data latch circuit, the lower data of the LM flag is read from the redundancy column storing the LM flag into the data latch circuit, the address of the redundancy column storing the LM flag is generated based on the address of the LM flag, and then the lower data of the LM flag is forcefully inverted in the data latch circuit by using the address of the redundancy column storing the LM flag.

2. General View

First, a multi-level NAND flash memory according to the embodiment will be described. Note that the multi-level NAND flash memory represents a NAND flash memory which stores 3- or higher-level data in a memory cell.

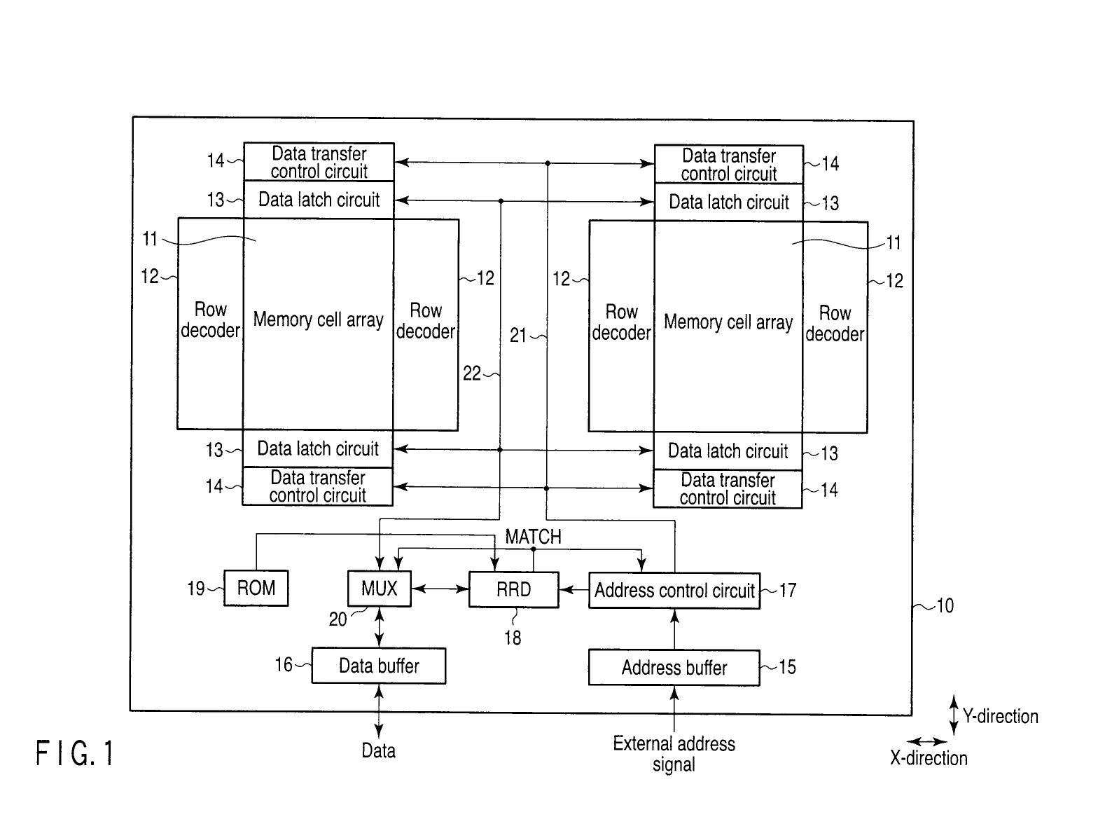

FIG. 1 shows an example of the multi-level NAND flash memory according to the embodiment.

Two memory cell arrays 11 are juxtaposed in the X-direction in multi-level NAND flash memory 10. Although there exist two memory cell arrays 11 in this example, one or more than two memory cell arrays 11 are also possible.

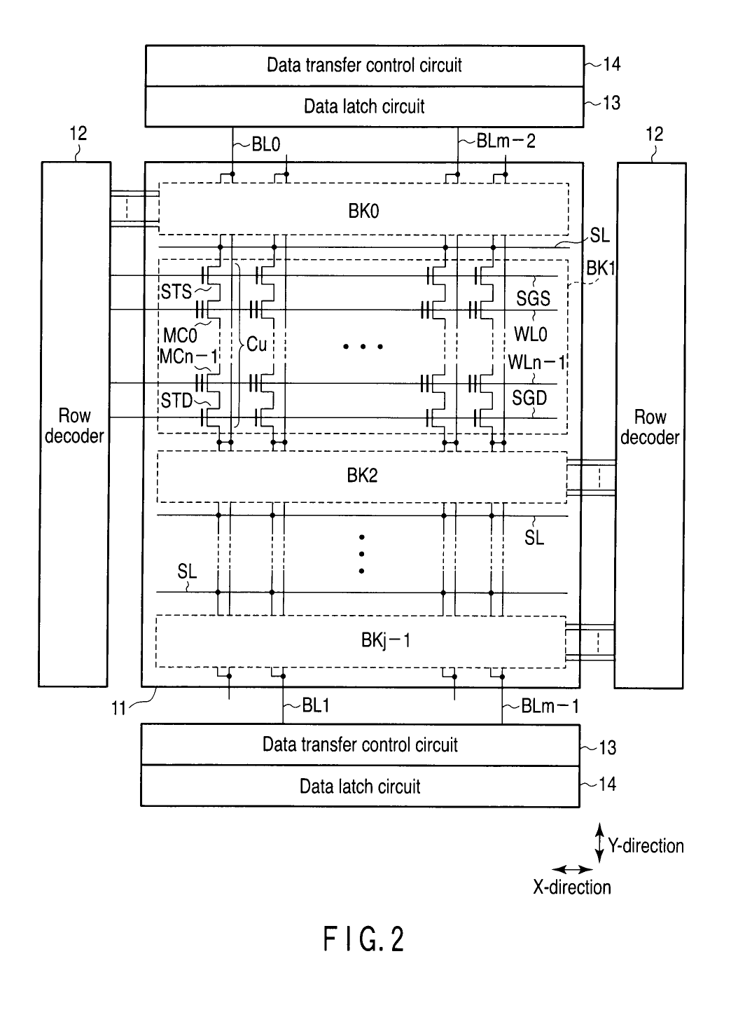

Memory cell array 11 includes, for example, j (j is a natural number of 2 or more) NAND blocks BK0, BK1, . . . , BKj-1 juxtaposed in the Y direction as shown in FIG. 2. Each of NAND blocks BK0, BK1, . . . , BKj-1 has NAND cell unit CU.

NAND cell unit CU includes n (n is a natural number of 2 or more) memory cells MC0, . . . , MCn-1 connected in series, and two select gate transistors STS and STD which are connected to both sides of the memory cells respectively.

In each of NAND blocks BK0, BK1, . . . , BKj-1, n word lines WL0, . . . , WLn-1 run in the X direction, and respectively connect to the control gates of memory cells MC0, . . . , MCn-1. Two select gate lines SGS and SGD run in the X direction, and respectively connect to the gates of two select gate transistors STS and STD.

Each of m (m is a natural number of 2 or more) bit lines BL0, BL1, . . . , BLm-2, BLm-1 runs in the Y direction, and connects to select gate transistor STD arranged on the drain side of corresponding NAND cell unit CU. Select gate transistor STS arranged on the source side of NAND cell unit CU is connected with a source line (cell source) SL.

Row decoder 12 is arranged on each side of memory cell array 11 in the X direction. Although row decoder 12 is arranged on each side of memory cell array 11 in the X direction in this example, it may be arranged on one side of memory cell array 11 in the X direction.

Data latch circuit 13 and data transfer control circuit 14 are arranged on each side of memory cell array 11 in the Y direction.

Data latch circuit 13 has a function of temporarily latching data in read/write operation. Data transfer control circuit 14 includes a column decoder, and controls data transfer for each column in memory cell array 11 in read/write operation.

In this example, data latch circuit 13 and data transfer control circuit 14 are arranged on each side of memory cell array 11 in the Y direction. Such floor plan is adopted, for example, when reading data from all bit lines in memory cell array 11.

Note that data latch circuit 13 and data transfer control circuit 14 may be arranged on one side of memory cell array 11 in the Y direction.

Address buffer 15 functions as an interface for an external address signal. Data buffer 16 functions as an interface for data.

An external address signal is input to address control circuit 17 via address buffer 15. Address control circuit 17 supplies an external column address signal to data transfer control circuit 14 via address bus 21, and also provides it to bad column data hold circuit (RRD: Registered Redundancy Data circuit) 18.

Bad column data hold circuit 18 has a function of temporarily holding the data of bad columns in read/write operation. Whether data is that of a bad column is determined by comparing the column address signal from address control circuit 17 with a bad column address signal stored in ROM 19.

Switch circuit 20 electrically connects two of data latch circuit 13, data buffer 16, and bad column data hold circuit 18 with each other. Switch circuit 20 includes, e.g., a multiplexer (MUX). Data are transferred between the two circuits electrically connected with each other via data bus 22.

In read/write operation, if an external address signal from outside multi-level NAND flash memory (e.g., a chip) 10 or an address signal (e.g., the address of the LM flag) stored in address control circuit 17 selects a bad column, bad column data hold circuit 18 outputs match signal MATCH.

Match signal MATCH is input to address control circuit 17 and switch circuit 20. Upon reception of match signal MATCH, address control circuit 17 prohibits access to the bad column, i.e., transfer of the external address signal to data transfer control circuit 14.

Upon reception of match signal MATCH in read operation, switch circuit 20 electrically connects data buffer 16 with bad column data hold circuit 18, and reads data from bad column data hold circuit 18.

Upon reception of match signal MATCH in write operation, switch circuit 20 electrically connects data buffer 16 with bad column data hold circuit 18, and writes data in bad column data hold circuit 18.

Multi-level NAND flash memory 10 is characterized by having bad column data hold circuit 18. Bad column data hold circuit 18 will be explained in detail below.

3. Bad Column Data Hold Circuit

A bad column data hold circuit is a component which is adopted for achieving high-speed read/write operation.

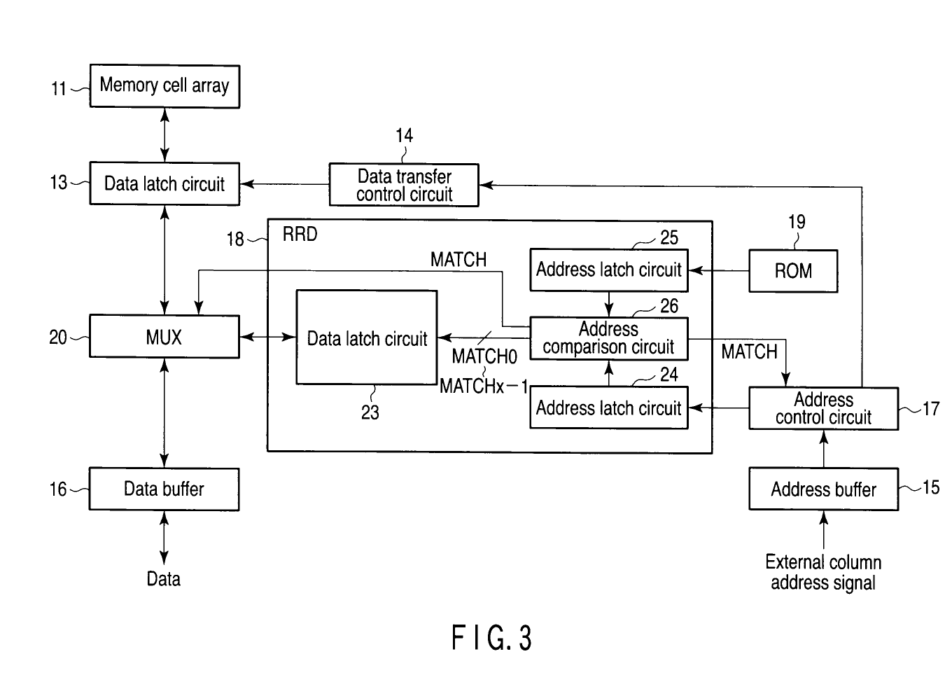

FIG. 3 shows a bad column data hold circuit.

Bad column data hold circuit 18 includes data latch circuit 23 for temporarily latching the data of a bad column, address latch circuit 24 for latching an external column address signal from address control circuit 17, address latch circuit 25 for latching a bad column address signal from ROM 19, and address comparison circuit 26 for comparing the external column address signal with the bad column address signal.

In read operation, the data of redundancy columns in memory cell array 11 are collectively transferred to data latch circuit 23 in bad column data hold circuit 18 via data latch circuit 13 in advance.

After that, when an external column address signal is input, address control circuit 17 transfers the external column address signal to bad column data hold circuit 18.

When the external column address signal selects a bad column, address comparison circuit 26 in bad column data hold circuit 18 outputs match signal MATCH (=“H”).

Match signal MATCH is obtained by calculating the OR (logical sum) of x (x is a natural number of 1 or more) match signals MATCH0 to MATCHx-1, and is input to address control circuit 17 and switch circuit 20. Note that x is equal to the number of the redundancy columns.

Upon reception of match signal MATCH, address control circuit 17 prohibits access to the bad column, i.e., transfer of the external address signal to data transfer control circuit 14. Upon reception of match signal MATCH, switch circuit 20 electrically connects data buffer 16 with bad column data hold circuit 18.

Furthermore, x match signals MATCH0 to MATCHx-1 output from address comparison circuit 26 are input to data latch circuit 23.

x match signals MATCH0 to MATCHx-1 correspond to the x redundancy columns. If the external column address signal matches the bad column address signal, one of x match signal MATCH0 to MATCHx-1 changes to “H”.

If, for example, match signal MATCH0 changes to “H”, the data of a bad column held in a corresponding latch circuit in data latch circuit 23 is output outside the multi-level NAND flash memory via switch circuit 20.

If the external column address signal selects a normal column, address control circuit 17 allows the external column address signal to be transferred to data transfer control circuit 14. Then, data is read from the normal column in memory cell array 11 selected by the external column address signal, as in a normal case.

In write operation, data to be written in a redundancy column in memory cell array 11 is transferred to data latch circuit 23 in bad column data hold circuit 18.

That is, when the external column address signal is input, address control circuit 17 transfers the external column address signal to bad column data hold circuit 18.

When the external column address signal selects a bad column, address comparison circuit 26 in bad column data hold circuit 18 outputs match signal MATCH (=“H”). Match signal MATCH is input to address control circuit 17 and switch circuit 20.

Upon reception of match signal MATCH, address control circuit 17 prohibits access to the bad column, i.e., transfer of the external column address signal to data transfer control circuit 14. Upon reception of match signal MATCH, switch circuit 20 electrically connects data buffer 16 with bad column data hold circuit 18.

Furthermore, x match signals MATCH0 to MATCHx-1 output from address comparison circuit 26 are input to data latch circuit 23.

As described above, x match signals MATCH0 to MATCHx-1 correspond to the x redundancy columns, as mentioned earlier. That is, if the external column address signal matches the bad column address signal, one of x match signals MATCH0 to MATCHx-1 changes to “H”.

If, for example, match signal MATCH0 changes to “H”, data is written in a corresponding latch circuit in data latch circuit 23.

After that, bad column data hold circuit 18 collectively transfers the data of bad columns from data latch circuit 23 to the redundancy columns via switch circuit 20.

If the external column address signal selects a normal column, address control circuit 17 allows the external column address signal to be transferred to data transfer control circuit 14. Then, data is written in the normal column in memory cell array 11 selected by the external column address signal, as in a normal case.

4. LM (Lower Middle) Mode

In the embodiment, assume that a technique called the LM mode is adopted for write operation of 3- or higher-level data.

The LM mode is an effective technique for preventing the threshold of a memory cell from fluctuating in accordance with the threshold of an adjacent memory cell, i.e., preventing the adverse influence of a capacitive coupling effect, by controlling the threshold distribution of 3- or higher-level data.

The LM mode will be explained below.

Note that multi-level data is 4-level data (2-bit data) in the following explanation for descriptive convenience. When “QR” (Q and R are 0 or 1, respectively) is presented, Q indicates upper data; and R, lower data.

(1) Threshold Distribution of Memory Cell

The threshold distribution of a memory cell in adopting the LM mode will be described first.

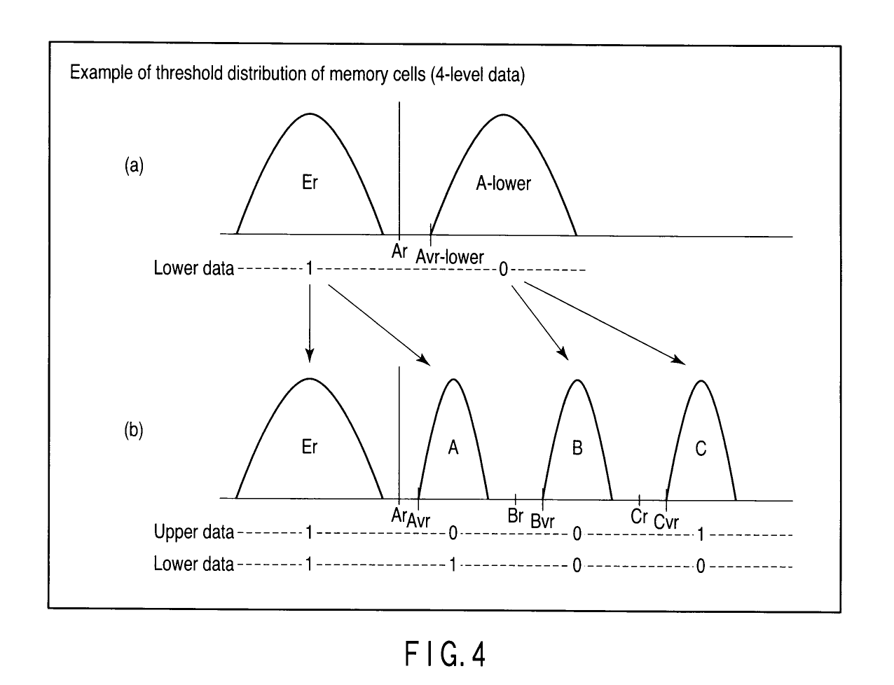

FIG. 4 shows an example of the threshold distribution of a memory cell.

In (a) of FIG. 4, lower data has been written.

The initial state of a memory cell is an erased state, and its threshold distribution is Er. If the lower data is “1”, write operation is prohibited, and the threshold distribution of the memory cell remains Er. In contrast to this, if the lower data is “0”, write operation is performed, and the threshold distribution of the memory cell shifts from Er to A-lower.

Write-verify read operation is executed by providing a target memory cell with Avr-lower as a read potential. Normal read operation is performed by providing a target memory cell with Ar as a read potential.

In a state in which only the lower data has been written, threshold distribution A-lower of a memory cell with lower data “0” is different from that of a memory cell with both lower and upper data written as shown in (b) of FIG. 4.

This state will be referred to as a rough writing state, or an LM (Lower Middle) state since threshold distribution A-lower is situated at the center of threshold distributions Er, A, B, and C in (b) of FIG. 4.

The capacitive coupling effect, therefore, does not adversely affect a memory cell with only lower data written.

In (b) of FIG. 4, lower and upper data have been written.

When storing 2-level data in a memory cell capable of storing 4-level data, the 2-level data is stored as lower data. When storing 4-level data in a memory cell capable of storing 4-level data, upper data is written after writing lower data.

In the following, assume that lower data has been written. A case in which upper data is written in this state will now be explained.

A case in which the lower data is “1” will be described first.

If the upper data is “1”, write operation is prohibited and, therefore, the threshold distribution of the memory cell remains Er. Alternatively, if the upper data is “0”, write operation is performed, and the threshold distribution of the memory cell shifts from Er to A.

Next, a case in which the lower data is “0” will be explained.

In this case, if the upper data is “1”, write operation is executed, and the threshold distribution of the memory cell shifts from A-lower to C. Alternatively, if the upper data is “0”, write operation is performed, and the threshold distribution of the memory cell shifts from A-lower to B.

Write-verify read operation is performed by providing a target memory cell with Avr, Bvr, or Cvr as a read potential. Normal read operation is executed by providing a target memory cell with Ar, Br, or Cr as a read potential.

Note that when writing the upper data in the state in which the lower data has been written, the threshold distribution shift amount becomes smaller in the order of a shift amount from Er to A, that from A-lower to B, and that from A-lower to C.

This, therefore, deters the threshold distribution from spreading due to the capacitive coupling effect produced in writing the upper data.

(2) LM (Lower Middle) Flag

It is determined by using the LM flag whether a memory cell on which read/write operation is performed stores only lower data or both lower and upper data.

The LM flag will be described below.

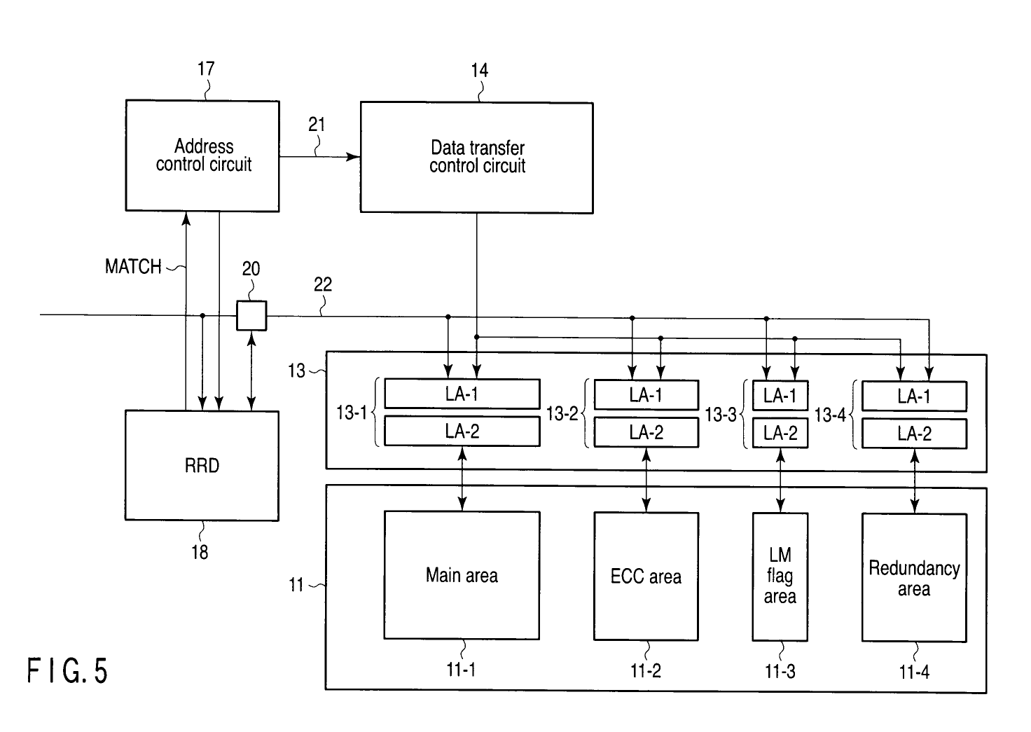

FIG. 5 shows details of a memory cell array core part.

The memory cell array core part includes memory cell array 11, data latch circuit 13, and data transfer control circuit 14. Address control circuit 17 and bad column data hold circuit (RRD) 18 constitute peripheral circuits.

Reference numeral 21 denotes an address bus; and 22, a data bus.

Memory cell array 11 includes main area 11-1 storing main data (e.g., file data), ECC (Error Correct Circuit) area 11-2 storing data for data correction by an ECC, LM flag area 11-3 storing the LM flag, and redundancy area 11-4 storing redundancy data.

Data latch circuit 13 includes first latch circuit LA-1 and second latch circuit LA-2. Two latch circuits LA-1 and LA-2 are used for reading/writing 4-level (2-bit) data.

Data latch circuit 13-1 corresponds to main area 11-1; data latch circuit 13-2, ECC area 11-2; data latch circuit 13-3, LM flag area 11-3; and data latch circuit 13-4, redundancy area 11-4.

Note that the LM flag is provided for each row (e.g., each page), and is used to determine whether a memory cell in the row stores only lower data or both lower and upper data.

Patent references 1 to 3, for example, have disclosed the LM flag. In these references, the value of the LM flag is determined to be “L” if a memory cell only stores lower data, and the value of the LM flag is determined to be “H” if a memory cell stores both lower and upper data.

These references, however, do not consider the threshold distribution of the LM flag.

That is, when the LM flag is “L”, its threshold distribution can be assumed to be Er. When the LM flag is “H”, however, whether the threshold distribution is A, B, or C is unknown.

Now, consider the threshold distribution of the LM flag.

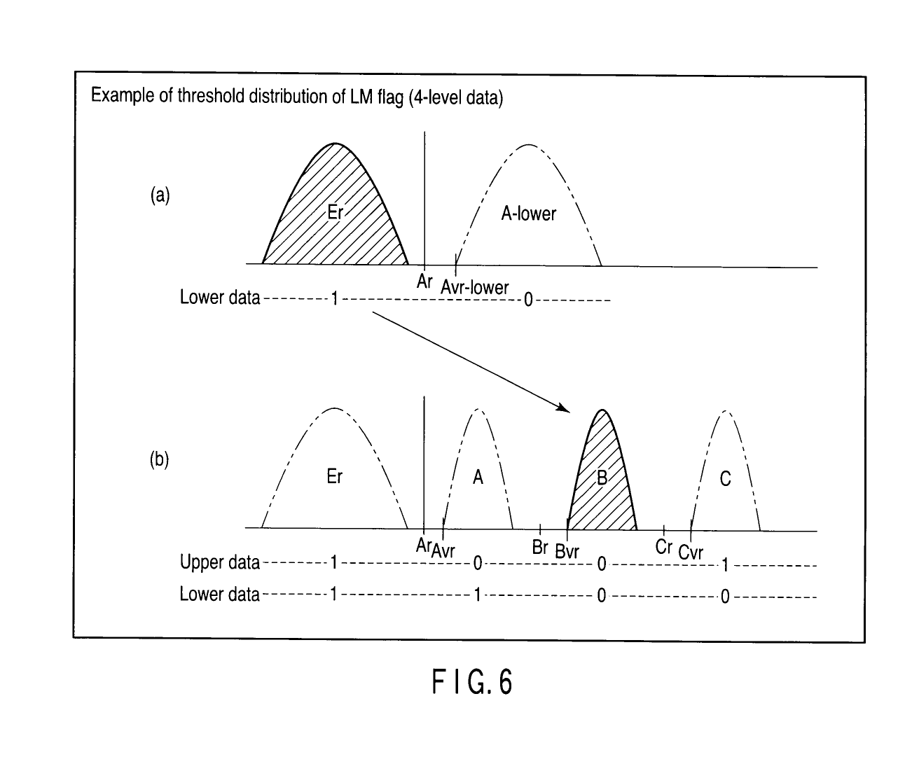

FIG. 6 shows an example of the threshold distribution of the LM flag.

In this example, assume that the LM flag includes one memory cell, and is provided for each row (e.g. each page).

If only lower data is written in a memory cell of the main area, only lower data needs to be written for the LM flag. This is because the memory cell of the main area and the LM flag are connected to a word line common to them, and are read at the same read potential.

In this case, the threshold distribution of the LM flag is set to erased state Er.

Since the LM flag data “L”, i.e., the lower data “1” is read at read potential Ar, it is possible to recognize that the memory cell only stores the lower data.

For the same reason, if both lower and upper data are written in the memory cell of the main area, both the lower and upper data need to be written for the LM flag.

In this case, the threshold distribution of the LM flag is set to writing state B.

The reason for this is that when reading 4-level data, the data is read using Br between threshold distributions A and B as a read potential first and then the value of lower data is determined. Furthermore, in this case, the value of the LM flag is preferably determined to be “H”.

For threshold distribution C, the value of the LM flag can also be determined to be “H” based on read potential Br. A smaller threshold shift amount from Er is preferred.

Therefore, when both the lower and upper data are written in the memory cell of the main area, the threshold distribution of the LM flag is set to writing state B.

Since the LM flag data “H”, i.e., the lower data “0” is read at read potential Br, it is possible to recognize that the memory cell stores both the lower and upper data.

(3) Write Operation of LM Flag

As described above, the threshold distribution of the LM flag is Er in a state in which only lower data has been written in the memory cell of the main area, and the threshold distribution is B in a state in which both lower and upper data have been written in the memory cell of the main area.

As described above for the threshold distribution of the memory cell (FIG. 4), threshold distribution Er cannot shift to threshold distribution B in principle.

This is caused by the write principles of multi-level data.

The write principles will now be explained.

First, lower data is written based on the value of the lower data as write data.

The lower data is latched into first latch circuit LA-1 of FIG. 5. If the lower data is “1”, write operation is prohibited. If the lower data is “0”, write operation is performed. When the threshold becomes Avr-lower or more in FIG. 4 by executing write-verify read operation, the lower data latched into first latch circuit LA-1 of FIG. 5 is changed from “0” to “1”, thereby terminating the write operation.

Upper data is written based on the value of the lower data and the value of the upper data as write data.

First, the lower data is latched into first latch circuit LA-1 of FIG. 5, and the upper data is latched into second latch circuit LA-2 of FIG. 5. If both the lower and upper data are “1”, write operation is prohibited; otherwise, write operation is executed.

If the lower data is “1” and the upper data is “0”, write operation is performed. If the threshold falls within the range from Avr (inclusive) to Bvr (exclusive) in FIG. 4 by executing write-verify read operation, the upper data latched into second latch circuit LA-2 of FIG. 5 is changed from “0” to “1”, thereby terminating the write operation.

If the lower data is “0” and the upper data is “0”, write operation is executed. If the threshold falls within the range from Bvr (inclusive) to Cvr (exclusive) in FIG. 4 by executing write-verify read operation, the lower data latched into first latch circuit LA-1 and the upper data latched into second latch circuit LA-2 of FIG. 5 are changed from “0” to “1”, respectively, thereby terminating the write operation.

Furthermore, if the lower data is “0” and the upper data is “1”, write operation is performed. If the threshold becomes Cvr or more in FIG. 4 by executing write-verify read operation, the lower data latched into first latch circuit LA-1 of FIG. 5 is changed from “0” to “1”, thereby terminating the write operation.

According to the above write principles, it is impossible to shift to threshold distribution B if the data latched into first latch circuit LA-1 of FIG. 5 is “1”, but it is possible if the data is “0”. That is, the threshold distribution of a memory cell cannot shift from Er to B in principle.

When writing the upper data for the LM flag, the lower data “1” latched into first latch circuit LA-1 in data latch circuit 13-3 of FIG. 5 is forcefully changed to “0”.

Therefore, “0” is latched into first and second latch circuits LA-1 and LA-2 in data latch circuit 13-3 of FIG. 5 on the assumption that the upper data for the LM flag is “0”. The threshold distribution appears to shift from A to B, thereby effectively making it possible to shift from Er to B.

5. Write Procedure of Upper Data for LM Flag

The bad column data hold circuit and the LM mode on which the embodiment is based have been described above. Based on them, the embodiment relates to a write procedure of upper data (LM flag data) for the LM flag when a column storing the LM flag is a bad column.

If a column storing the LM flag is a bad column, access to the bad column is prohibited. As a result, the address of the LM flag assigns a data latch circuit in the bad column data hold circuit corresponding to a redundancy column replacing the bad column.

That is, it is impossible to directly access the redundancy column storing the LM flag.

An example of the write procedure will sequentially be explained below.

Assume that the write operation of lower data (LM flag data) is complete, and the threshold distribution of the LM flag at this time is in state Er. When writing the upper data, the threshold distribution of the LM flag shifts from Er to B as shown in FIG. 6.

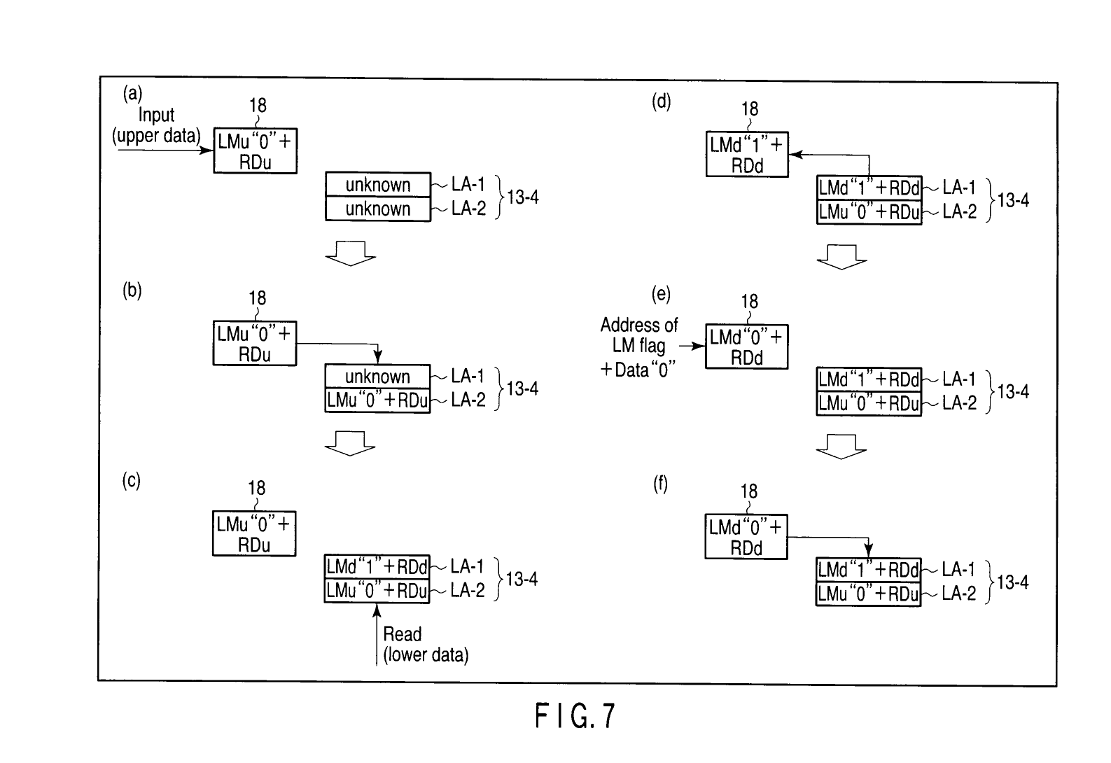

FIG. 7 shows a write procedure of upper data for the LM flag.

First, as shown in (a) of FIG. 7, when upper data for one page are input, the data of bad columns are input to bad column data hold circuit 18. That is, since a column storing the LM flag is a bad column, upper data (LM flag data LMu “0”) to be written in the LM flag is input to bad column data hold circuit 18.

Because there may exist bad columns other than the column storing the LM flag, upper data to be written in those columns are represented by RDu (“0” or “1”).

As described above, it is possible to readily determine whether data is that of a bad column, by comparing an external column address signal with a bad column address signal in bad column data hold circuit 18.

As shown in (b) of FIG. 7, data LMu “0”+RDu of the bad columns are collectively transferred from bad column data hold circuit 18 to second latch circuit LA-2 in data latch circuit 13-4 corresponding to the redundancy area.

This transfer operation is automatically executed by providing a means of sequentially incrementing a column address in the redundancy area from start to finish without using any external address signal.

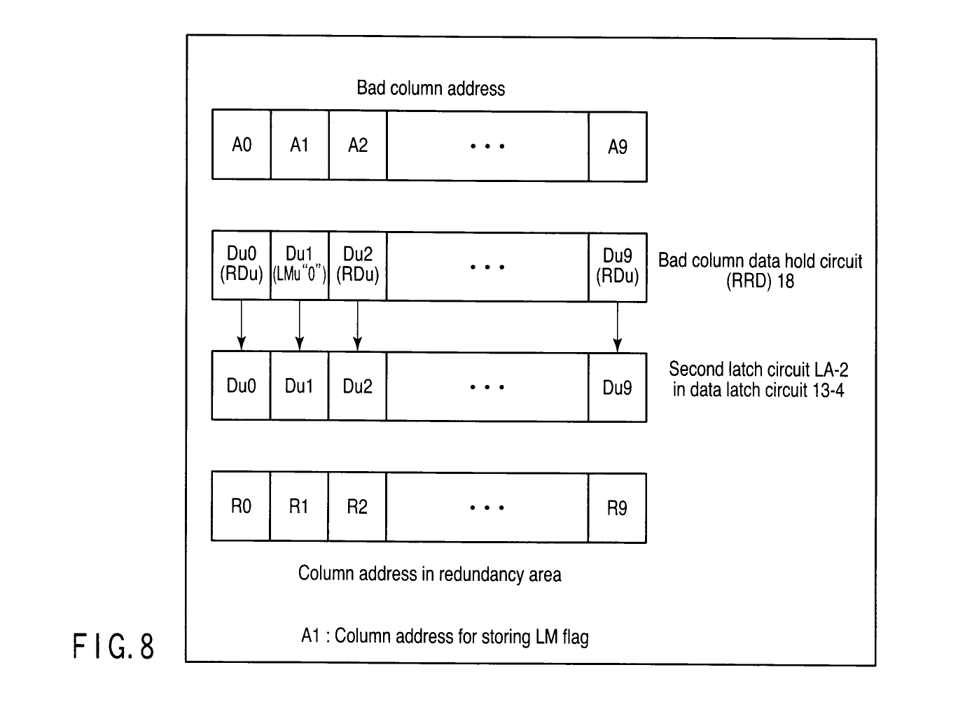

As shown in FIG. 8, for example, if there exist 10 bad columns A0 to A9, and 10 redundancy columns R0 to R9 in a redundancy area are used to fix them, upper data Du0 to Du9 of bad columns A0 to A9 are temporarily latched into bad column data hold circuit (RRD) 18.

Assume that bad column A1 serves as a column storing the LM flag, i.e., a column in an LM flag area. Data Du1 corresponds to LMu “0”, and remaining data Du0 and Du2 to Du9 correspond to RDu.

Data Du0 to Du9 of bad columns A0 to A9 are collectively transferred from bad column data hold circuit 18 to second latch circuit LA-2 in data latch circuit 13-4 corresponding to the redundancy area by sequentially incrementing a column address in the redundancy area from R0 to R9 by one.

Note that although the bad columns are denoted by reference symbols A0 to A9, they do not represent consecutive column addresses. This is because bad columns appear in any columns in a memory cell array.

As shown in (c) of FIG. 7, the lower data is read from a memory cell in the redundancy area.

Assume that lower data (LM flag data) read from the LM flag is represented by LMd “1”, and lower data read from bad columns other than the column storing the LM flag are indicated by RDd (“0” or “1”).

These lower data are latched into first latch circuit LA-1 in data latch circuit 13-4.

Then, as shown in (d) of FIG. 7, the lower data LMd “1”+RDd latched into first latch circuit LA-1 are collectively transferred to bad column data hold circuit 18.

This transfer operation is automatically executed by providing a means of sequentially incrementing a column address in a redundancy area from start to finish without using any external address.

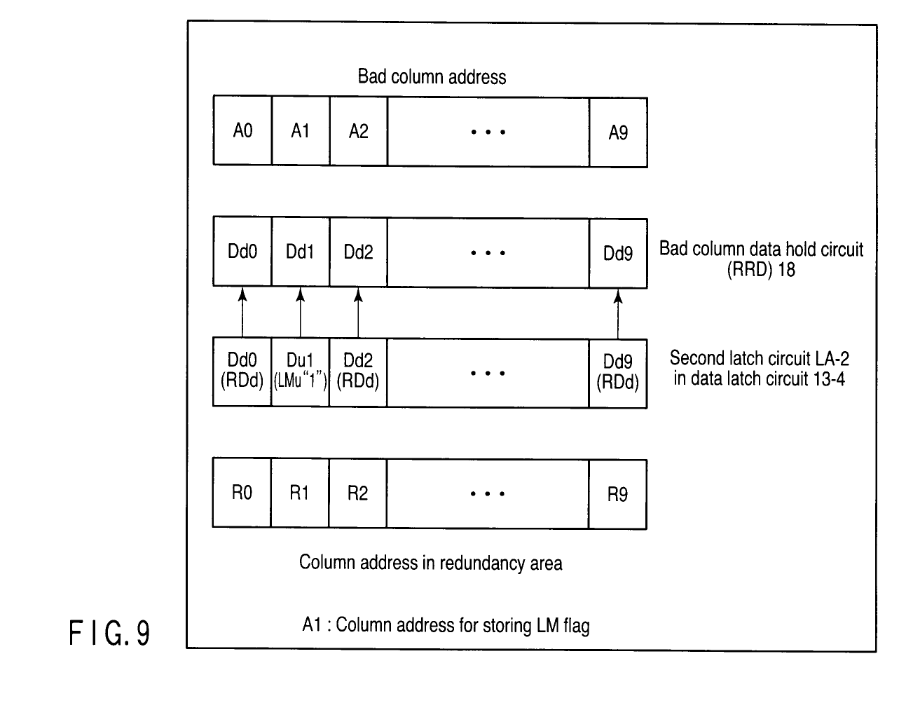

As shown in FIG. 9, for example, if there exist 10 bad columns A0 to A9, and 10 redundancy columns R0 to R9 in a redundancy area are used to fix them, lower data Dd0 to Dd9 of bad columns A0 to A9 are read into first latch circuit LA-1 in data latch circuit 13-4 corresponding to the redundancy area.

Assume that bad column Al serves as a column storing the LM flag, i.e., a column in an LM flag area. Data Dd1 corresponds to LMd “1”, and remaining data Dd0 and Dd2 to Dd9 correspond to RDd.

Data Dd0 to Dd9 of bad columns A0 to A9 are collectively transferred from first latch circuit LA-1 in data latch circuit 13-4 corresponding to the redundancy area to bad column data hold circuit (RRD) 18 by sequentially incrementing a column address in the redundancy area from R0 to R9 by one.

Note that although the bad columns are denoted by reference symbols A0 to A9, they do not represent consecutive column addresses. This is because bad columns appear in any columns in a memory cell array.

As shown in (e) of FIG. 7, the value of the lower data (LM flag data) read from the LM flag is forcefully changed from LMd “1” to LMd “0” in bad column data hold circuit 18.

The operation of forcefully changing the value of the lower data read from the LM flag from “1” to “0”, and shifting the threshold distribution from Er to B is called LM-dump.

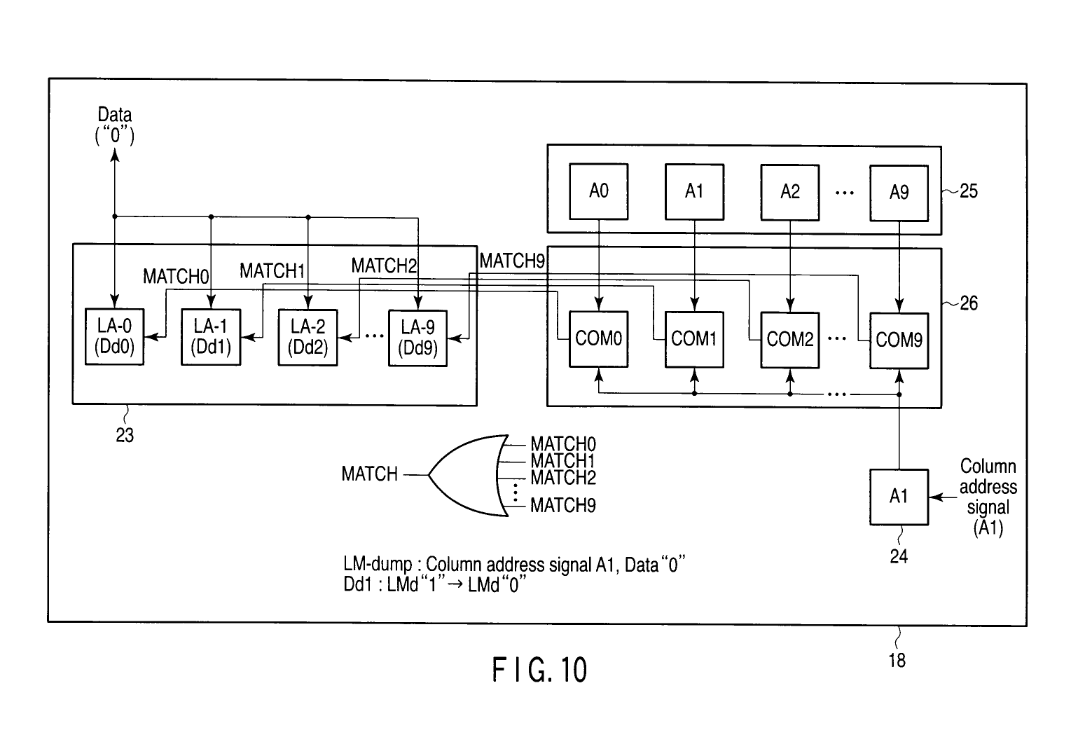

In LM-dump, for example, as shown in FIG. 10, column address signal A1 of the LM flag and data “0” are input to bad column data hold circuit 18.

Column address signal Al is latched into address latch circuit 24.

Match signal MATCH1 from comparator COM1 in address comparison circuit 26 changes to “H”. At this time, match signals MATCH0 and MATCH2 to MATCH 9 respectively from remaining comparators COM0 and COM2 to COM9 are “L”.

In data latch circuit 23, reference symbols LA0 to LA9 denote latch circuits; and Dd0 to Dd9, data (lower data read from redundancy columns) which are latched into latch circuits LA0 to LA9 at this time, respectively.

That is, Dd1 corresponds to LMd “1”, and Dd0 and Dd2 to Dd9 correspond to RDd.

In address latch circuit 24, reference symbol A1 denotes a column address signal. In address latch circuit 25, reference symbols A0 to A9 denote bad column addresses.

When match signal MATCH1 changes to “H”, a transfer gate in latch circuit LA-1 is turned on, and therefore, data “0” is input to latch circuit LA-1.

Data LMd “1” has already been latched into latch circuit LA-1 at this time. If data “0” is input, however, overwrite operation is performed in latch circuit LA-1, and the data latched into latch circuit LA-1 is forcefully changed from LMd “1” to LMd “0”.

As shown in (f) of FIG. 7, data LMd “0”+RDd of the bad columns are collectively transferred from bad column data hold circuit 18 to first latch circuit LA-1 in data latch circuit 13-4 corresponding to the redundancy area.

This transfer operation is automatically executed by providing a means of sequentially incrementing a column address in the redundancy area from start to finish without using any external address signal.

The transfer operation is performed in the same manner as the transfer operation of data LMu “0”+RDu of the bad columns in FIG. 8.

Consequently, first and second latch circuits LA-1 and LA-2 in data latch circuit 13-4 corresponding to the redundancy area latch “0”. If write operation is executed in this state, the threshold distribution of the LM flag shifts from Er to B as shown in FIG. 6.

In this write procedure, to write the upper data for the LM flag, the following operation is performed. That is, all the data of the bad columns are transferred from the data latch circuit corresponding to the redundancy area to the data latch circuit in the bad column data hold circuit, the lower data read from the LM flag in the bad column data hold circuit is forcefully changed from LMd “1” to LMd “0”, and then all the data of the bad columns are transferred from the data latch circuit in the bad column data hold circuit back to the data latch circuit corresponding to the redundancy area.

To only change the lower data of the LM flag, however, all the data of the bad columns are transferred between the data latch circuit corresponding to the redundancy area and that in the bad column data hold circuit, thereby making the write time longer.

This problem will be solved in the first to third embodiments to be described below.

In the write procedure explained above, in LM-dump, it is possible to recognize based on a match signal from the address comparison circuit that a redundancy column of the redundancy area stores the LM flag, but it is impossible to specifically assign the redundancy column (a replacement destination address).

In the first to third embodiments, there is proposed a means capable of specifically assigning, if a redundancy column of the redundancy area stores the LM flag, the redundancy column (a replacement destination address) in LM-dump.

If such means is provided, not all the data of the bad columns need to be transferred between the data latch circuit corresponding to the redundancy area and the bad column data hold circuit. It is possible to directly access the first latch circuit which latches the lower data of the LM flag, and to change the value of the lower data of the LM flag.

If the bad column data hold circuit is adopted, it is possible to write the LM flag data at a higher speed when a column (LM flag area) storing the LM flag is a bad column, thereby shortening the write time.

6. First Embodiment

In the first embodiment, there is proposed a technique of forcefully changing the value of lower data of an LM flag from “1” to “0” in a data latch circuit corresponding to a redundancy area by using a match signal generated by a bad column data hold circuit to assign a redundancy column (replacement destination address) storing the LM flag in LM-dump.

This eliminates the need for transferring all the data of bad columns between the data latch circuit corresponding to the redundancy area and that in the bad column data hold circuit in order to only change the lower data of the LM flag, thereby shortening the write time.

(1) Circuit Arrangement

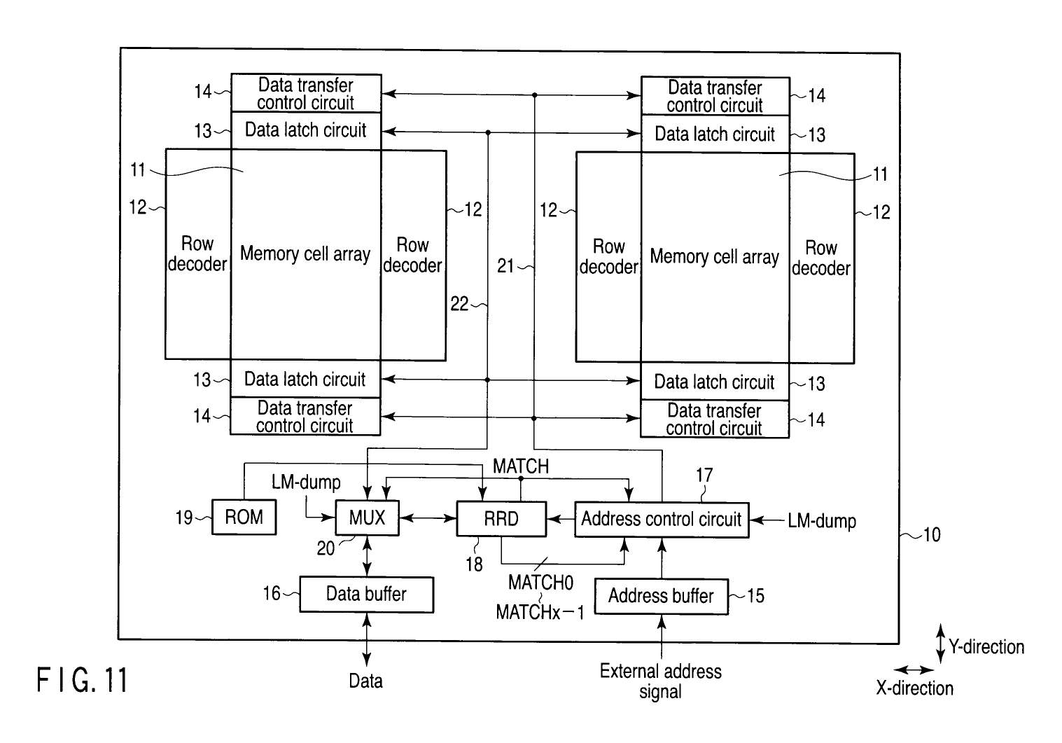

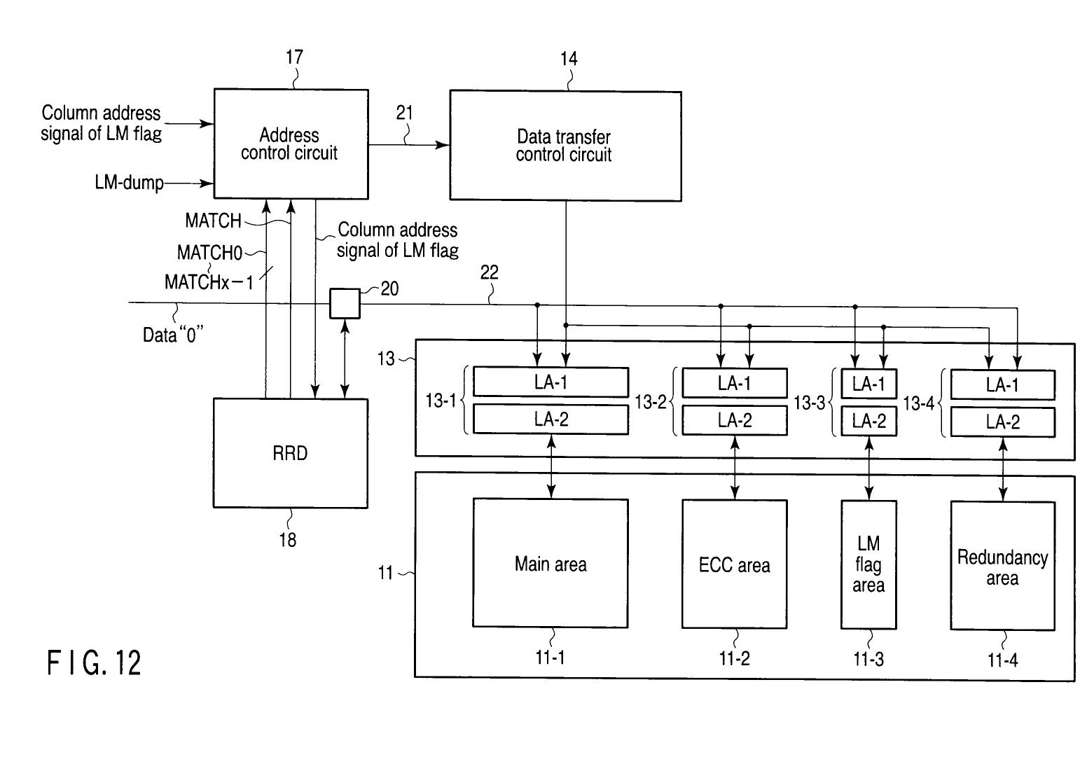

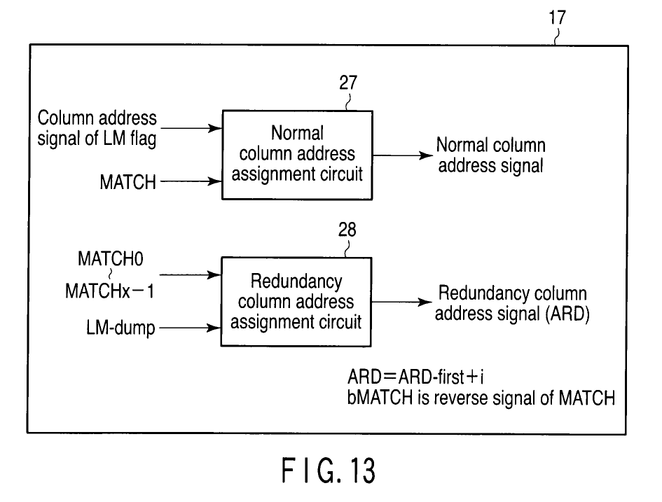

FIGS. 11, 12 and 13 show the circuit arrangement of a multi-level NAND flash memory according to the first embodiment.

Memory cell array 11, row decoder 12, data latch circuit 13, data transfer control circuit 14, address buffer 15, and data buffer 16 in multi-level NAND flash memory 10 have already been explained in detail above for FIGS. 1 and 5, and a description thereof will be omitted.

An external address signal is input to address control circuit 17 via address buffer 15. Address control circuit 17 supplies an external column address signal to data transfer control circuit 14 via address bus 21, and also provides it to bad column data hold circuit (RRD) 18.

Bad column data hold circuit 18 has a function of temporarily holding the data of bad columns in read/write operation. Whether data is that of a bad column is determined by comparing the column address signal from address control circuit 17 with a bad column address signal stored in ROM 19.

Bad column data hold circuit 18 has the circuit arrangement shown in FIGS. 3 and 10.

Details of the circuit arrangement have already been explained in detail above for FIGS. 3 and 10, and a description thereof will be omitted.

Switch circuit (MUX) 20 electrically connects two of data latch circuit 13, data buffer 16, and bad column data hold circuit 18 with each other. Data are transferred between the two circuits electrically connected with each other via data bus 22.

In read/write operation, if an external address signal from outside multi-level NAND flash memory (e.g., a chip) 10 or an address signal (e.g., the address of the LM flag) stored in address control circuit 17 selects a bad column, bad column data hold circuit 18 outputs match signal MATCH.

Match signal MATCH is input to address control circuit 17 and switch circuit 20. Upon reception of match signal MATCH, address control circuit 17 prohibits access to the bad column, i.e., transfer of the external address signal to data transfer control circuit 14.

Upon reception of match signal MATCH in read operation, switch circuit 20 electrically connects data buffer 16 with bad column data hold circuit 18, and reads data from bad column data hold circuit 18.

Upon reception of match signal MATCH in write operation, switch circuit 20 electrically connects data buffer 16 with bad column data hold circuit 18, and writes data in bad column data hold circuit 18.

In LM-dump, if the column address signal (external address signal) of the LM flag selects a bad column, bad column data hold circuit 18 outputs, for example, x (x is a natural number of 1 or more) match signals MATCH0 to MATCHx-1.

The order of x data latch circuits in bad column data hold circuit 18 corresponds, for example, to that of x redundancy columns in the redundancy area.

It is possible to know which one of the x redundancy columns in the redundancy area has been selected by checking which one of x match signals MATCH0 to MATCHx-1 corresponding to the x data latch circuits changed to “H”.

Therefore, x match signals MATCH0 to MATCHx-1 are input to address control circuit 17.

In addition to normal column address assignment circuit 27, address control circuit 17 has redundancy column address assignment circuit 28. If match signal MATCH is “H”, address control circuit 17 deactivates normal column address assignment circuit 27.

If control signal LM-dump indicating that LM-dump is executed changes to “H”, address control circuit 17 activates redundancy column address assignment circuit 28.

Redundancy column address assignment circuit 28 stores nonvolatile first address ARD-first of a redundancy column in the redundancy area.

For this reason, it is possible to generate a redundancy column (replacement destination address) storing the LM flag by adding, to first address ADR-first, the ordinal number i (i is between 0 and x-1) of match signal MATCHi which has changed to “H”.

Upon reception of control signal LM-dump, switch circuit 20 electrically connects data transfer control circuit 14 with data buffer 16, and transfers data “0” input in LM-dump to data latch circuit 13 regardless of match signal MATCH from bad column data hold circuit 18.

In LM-dump, therefore, it is possible to forcefully change the value of the lower data of the LM flag from “1” to “0” in the data latch circuit corresponding to the redundancy area.

This eliminates the need for transferring all the data of bad columns between the data latch circuit corresponding to the redundancy area and that in the bad column data hold circuit in order to only change the lower data of the LM flag, thereby shortening the write time.

(2) Write Procedure of Upper Data for LM Flag

A write procedure of the upper data for the LM flag according to the first embodiment will be described.

Assume that a redundancy column stores the LM flag. Assume also that the write operation of the lower data (LM flag data) is complete, and the threshold distribution of the LM flag at this time is in state Er. Furthermore, when writing the upper data, the threshold distribution of the LM flag shifts from Er to B as shown in FIG. 6.

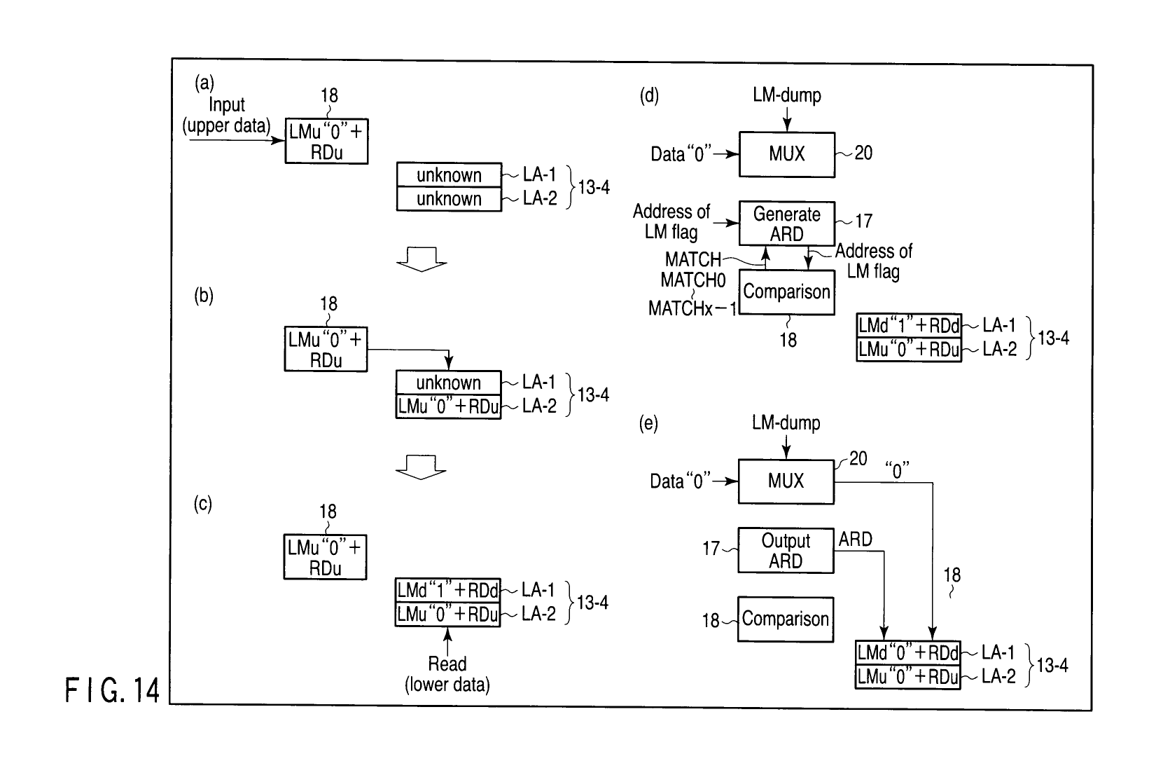

FIG. 14 shows a write procedure of upper data for the LM flag.

As shown in (a) of FIG. 14, when upper data for one page are input, the data of bad columns are input to bad column data hold circuit 18. That is, since a column storing the LM flag is a bad column, upper data (LM flag data LMu “0”) to be written in the LM flag is input to bad column data hold circuit 18.

Because there may exist bad columns other than the column storing the LM flag, upper data to be written in those columns are represented by RDu (“0” or “1”).

As described above, it is possible to readily determine whether data is that of a bad column, by comparing an external column address signal with a bad column address signal in bad column data hold circuit 18.

As shown in (b) of FIG. 14, data LMu “0”+RDu of the bad columns are collectively transferred from bad column data hold circuit 18 to second latch circuit LA-2 in data latch circuit 13-4 corresponding to the redundancy area.

This transfer operation is automatically executed by providing a means of sequentially incrementing a column address in the redundancy area from start to finish without using any external address signal, as described in FIGS. 7 and 8.

As shown in (c) of FIG. 14, lower data is read from a memory cell in the redundancy area.

Assume that lower data (LM flag data) read from the LM flag is represented by LMd “1”, and lower data read from bad columns other than the column storing the LM flag are indicated by RDd (“0” or “1”).

These lower data are latched into first latch circuit LA-1 in data latch circuit 13-4.

Then, LM-dump is executed as shown in (d) and (e) of FIG. 14.

More specifically, as shown in (d) of FIG. 14, the address (external column address signal) of the LM flag is input to bad column data hold circuit 18 via address control circuit 17.

Upon confirming that the column address signal of the LM flag matches the bad column address signal, bad column data hold circuit 18 outputs, e.g., match signal MATCH=“H”, i.e., MATCH1=“H”.

Upon reception of match signal MATCH=“H”, address control circuit 17 prohibits access using the address (external column address signal) of the LM flag.

Address control circuit 17 adds the ordinal number i (=1) of match signal MATCH1 to first address ADR-first of a redundancy column to generate address (column address signal) ARD=ARD-first+1 of a redundancy column storing the LM flag.

As shown in (e) of FIG. 14, address control circuit 17 then permits access using redundancy column address ARD.

Based on the received control signal LM-dump, switch circuit 20 transfers data “0” to first latch circuit LA-1 in data latch circuit 13-4 regardless of match signal MATCH from bad column data hold circuit 18.

Of lower data LMd “1”+RDd latched into first latch circuit LA-1 in data latch circuit 13-4, only lower data LMd “1” of the LM flag is forcefully changed to LMd “0”.

With this operation, first and second latch circuits LA-1 and LA-2 in data latch circuit 13-4 corresponding to the redundancy area latch “0”. In this state, when write operation is executed, the threshold distribution of the LM flag shifts from Er to B as shown in FIG. 6.

(3) Summary

According to the first embodiment, in LM-dump, it is possible to forcefully change the value of the lower data of the LM flag from “1” to “0” in the data latch circuit corresponding to the redundancy area by using a match signal generated by the bad column data hold circuit to assign a redundancy column (replacement destination address) storing the LM flag.

This eliminates the need for transferring all the data of bad columns between the data latch circuit corresponding to the redundancy area and that in the bad column data hold circuit in order to only change the lower data of the LM flag, thereby shortening the write time.

7. Second Embodiment

In the second embodiment, an LM flag redundancy circuit (LMRD) which stores the bad information of an LM flag and a redundancy column (replacement destination address) storing the LM flag is newly provided in a data transfer control circuit.

The LM flag redundancy circuit is activated in LM dump. If a column storing the LM flag is a bad column, the LM flag redundancy circuit executes access using the redundancy column (replacement destination address) storing the LM flag. Whether a column storing the LM flag is a bad column is determined based on the bad information of the LM flag.

This makes it possible to forcefully change the value of the lower data of the LM flag from “1” to “0” in a data latch circuit corresponding to a redundancy area. Not all the data of bad columns need to be transferred between the data latch circuit corresponding to the redundancy area and that in a bad column data hold circuit, thereby shortening the write time.

(1) Circuit Arrangement

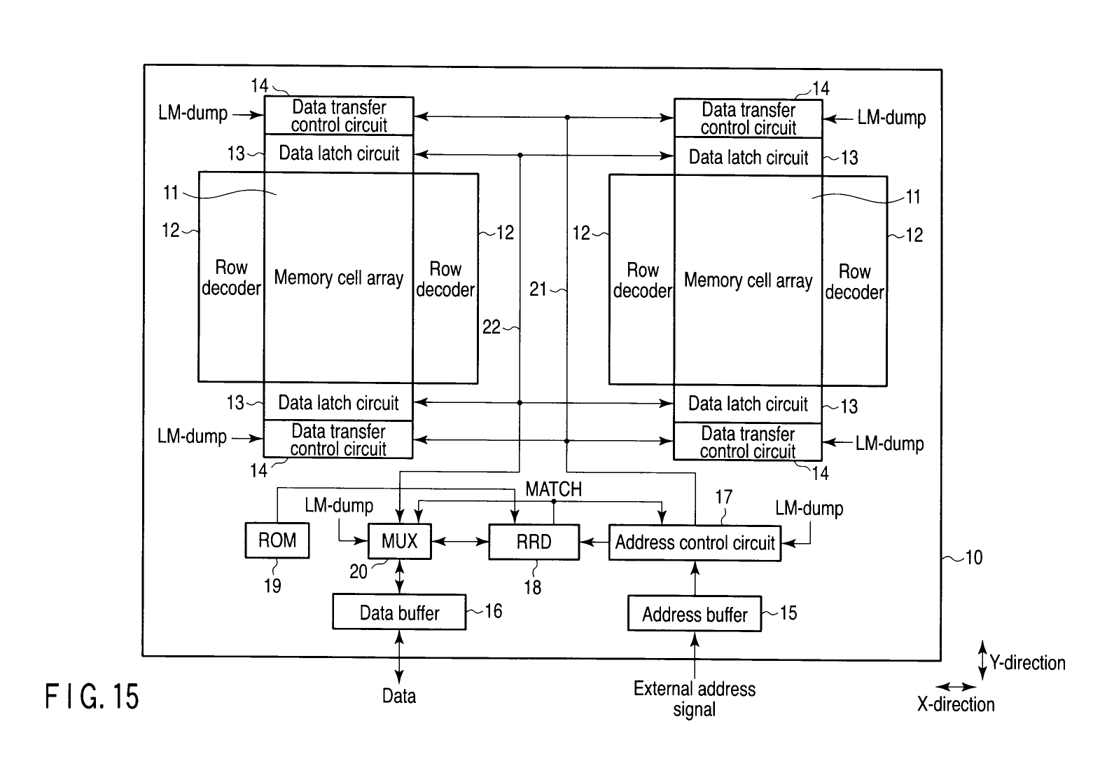

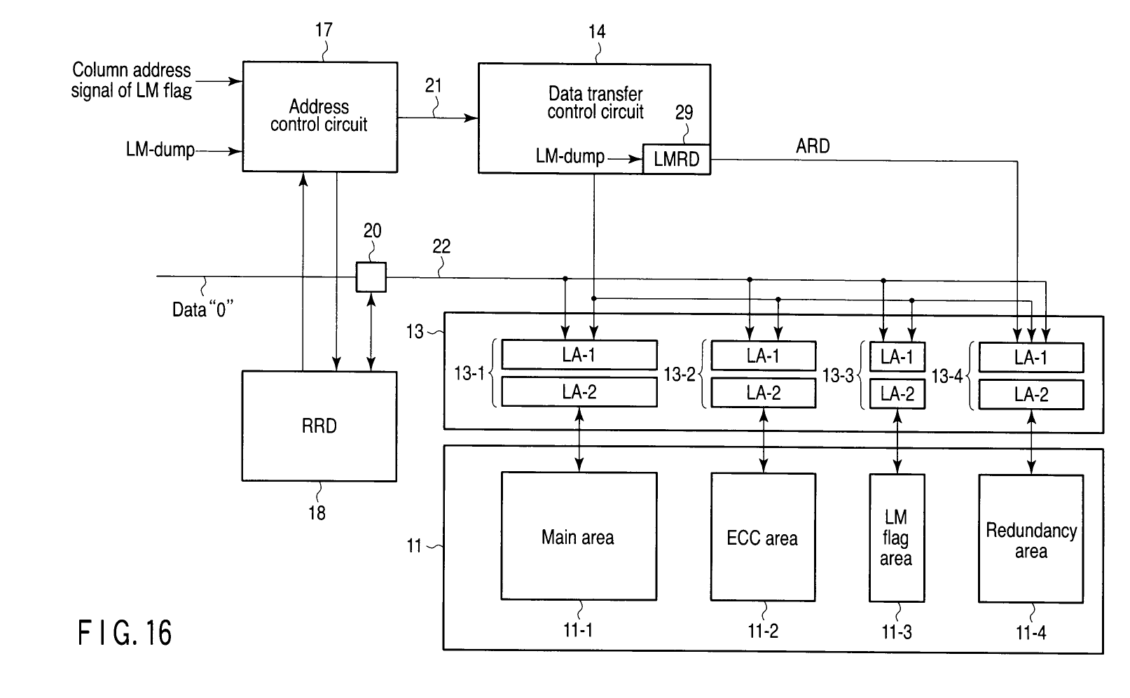

FIGS. 15 and 16 show the circuit arrangement of a multi-level NAND flash memory according to the second embodiment.

Memory cell array 11, row decoder 12, data latch circuit 13, data transfer control circuit 14, address buffer 15, and data buffer 16 in multi-level NAND flash memory 10 have already been explained in detail above for FIGS. 1 and 5, and a description thereof will be omitted.

An external address signal is input to address control circuit 17 via address buffer 15. Address control circuit 17 supplies an external column address signal to data transfer control circuit 14 via address bus 21, and also provides it to bad column data hold circuit (RRD) 18.

Bad column data hold circuit 18 has a function of temporarily holding the data of bad columns in read/write operation. Whether data is that of a bad column is determined by comparing the column address signal from address control circuit 17 with a bad column address signal stored in ROM 19.

Bad column data hold circuit 18 has the circuit arrangement shown in FIGS. 3 and 10.

Details of the circuit arrangement have already been explained in detail above for FIGS. 3 and 10, and a description thereof will be omitted.

Switch circuit (MUX) 20 electrically connects two of data latch circuit 13, data buffer 16, and bad column data hold circuit 18 with each other. Data are transferred between the two circuits electrically connected with each other via data bus 22.

In read/write operation, if an external address signal from outside multi-level NAND flash memory (e.g., a chip) 10 or an address signal (e.g., the address of the LM flag) stored in address control circuit 17 selects a bad column, bad column data hold circuit 18 outputs match signal MATCH.

Match signal MATCH is input to address control circuit 17 and switch circuit 20. Upon reception of match signal MATCH, address control circuit 17 prohibits access to the bad column, i.e., transfer of the external address signal to data transfer control circuit 14.

Upon reception of match signal MATCH in read operation, switch circuit 20 electrically connects data buffer 16 with bad column data hold circuit 18, and reads data from bad column data hold circuit 18.

Upon reception of match signal MATCH in write operation, switch circuit 20 electrically connects data buffer 16 with bad column data hold circuit 18, and writes data in bad column data hold circuit 18.

Upon reception of control signal LM-dump, address control circuit 17 transfers the column address signal of the LM flag to data transfer control circuit 14 regardless of whether the column address signal of the LM flag assigns a bad column, i.e., regardless of match signal MATCH from bad column data hold circuit 18.

Upon reception of control signal LM-dump, LM flag redundancy circuit 29 in data transfer control circuit 14 is activated. If a column storing the LM flag is a bad column, LM flag redundancy circuit 29 generates address (replacement destination address) ARD of a redundancy column storing the LM flag, thereby executing access using address ARD.

Whether a column storing the LM flag is a bad column is determined by comparing the externally input column address signal of the LM flag with the nonvolatile bad information (column address signal) of the LM flag stored in LM flag redundancy circuit 29.

With respect to redundancy column address ARD storing the LM flag, there should be a correspondence between bad column data hold circuit 18 and LM flag redundancy circuit 29.

Upon reception of control signal LM-dump, switch circuit 20 electrically connects data transfer control circuit 14 with data buffer 16, and transfers data “0” input in LM-dump to data latch circuit 13-1, regardless of match signal MATCH from bad column data hold circuit 18.

It is, therefore, possible to forcefully change the value of the lower data of the LM flag from “1” to “0” in a data latch circuit corresponding to a redundancy area in LM-dump.

This eliminates the need for transferring all the data of bad columns between the data latch circuit corresponding to the redundancy area and that in the bad column data hold circuit in order to only change the lower data of the LM flag, thereby shortening the write time.

(2) Write Procedure of Upper Data for LM Flag

A write procedure of upper data for the LM flag according to the second embodiment will be described.

Assume that a redundancy column stores the LM flag. Assume also that the write operation of the lower data (LM flag data) is complete, and the threshold distribution of the LM flag at this time is in state Er. Furthermore, when writing upper data, the threshold distribution of the LM flag shifts from Er to B as shown in FIG. 6.

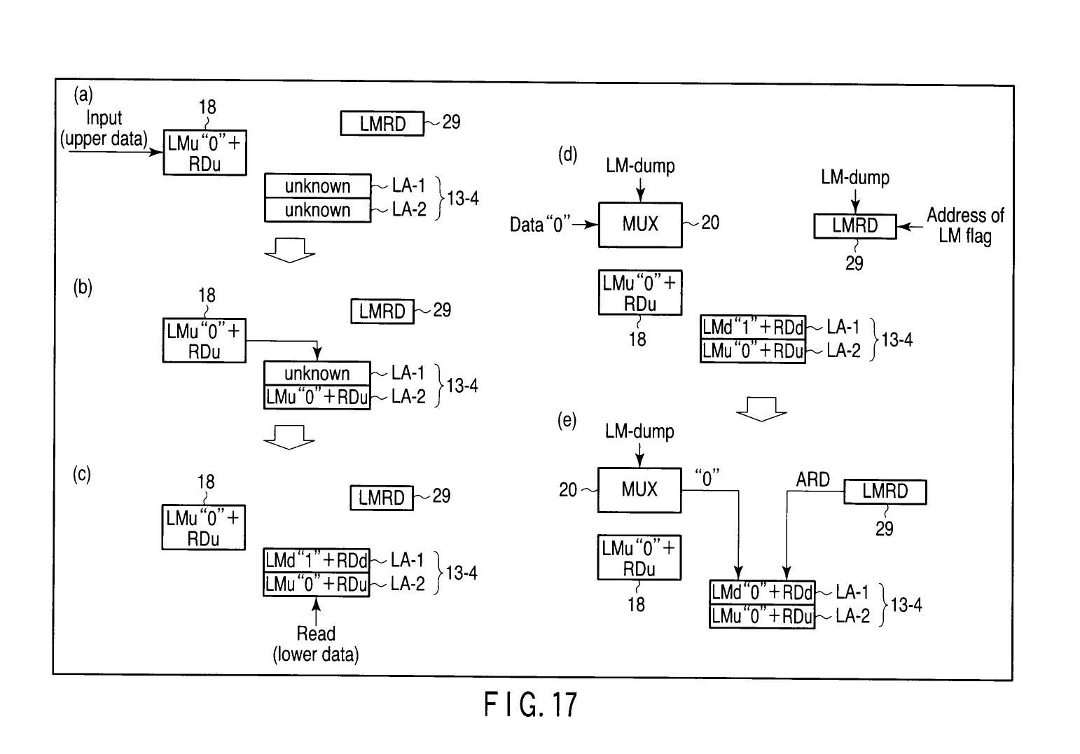

FIG. 17 shows a write procedure of upper data for the LM flag.

As shown in (a) of FIG. 17, when upper data for one page are input, the data of bad columns are input to bad column data hold circuit 18. That is, since a column storing the LM flag is a bad column, upper data (LM flag data LMu “0”) to be written in the LM flag is input to bad column data hold circuit 18.

Because there may exist bad columns other than the column storing the LM flag, upper data to be written in those columns are represented by RDu (“0” or “1”).

As described above, it is possible to readily determine whether data is that of a bad column, by comparing an external column address signal with a bad column address signal in bad column data hold circuit 18.

As shown in (b) of FIG. 17, data LMu “0”+RDu of the bad columns are collectively transferred from bad column data hold circuit 18 to second latch circuit LA-2 in data latch circuit 13-4 corresponding to a redundancy area.

This transfer operation is automatically executed by providing a means of sequentially incrementing a column address in the redundancy area from start to finish without using any external address signal as described in FIGS. 7 and 8.

As shown in (c) of FIG. 17, lower data is read from a memory cell in the redundancy area.

Assume that lower data (LM flag data) read from the LM flag is represented by LMd “1”, and lower data read from bad columns other than the column storing the LM flag are indicated by RDd (“0” or “1”).

These lower data are latched into first latch circuit LA-1 in data latch circuit 13-4.

Then, LM-dump is executed as shown in (d) and (e) of FIG. 17.

More specifically, as shown in (d) of FIG. 17, since control signal LM-dump changes to “H”, the address (external column address signal) of the LM flag is input to LM flag redundancy circuit (LMRD) 29 in the data transfer control circuit via the address control circuit.

Upon reception of control signal LM-dump, LM flag redundancy circuit 29 is activated. If a column storing the LM flag is determined to be a bad column based on the bad information of the LM flag, LM flag redundancy circuit 29 generates address (replacement destination address) ARD of a redundancy column storing the LM flag.

As shown in (e) of FIG. 17, the redundancy column storing the LM flag is accessed based on redundancy column address ARD output from LM flag redundancy circuit 29.

Based on the received control signal LM-dump, switch circuit 20 transfers data “0” to first latch circuit LA-1 in data latch circuit 13-4 regardless of match signal MATCH from bad column data hold circuit 18.

Of lower data LMd “1”+RDd latched into first latch circuit LA-1 in data latch circuit 13-4, only lower data LMd “1” of the LM flag is forcefully changed to LMd “0”.

Note that access to the bad column by using the address (external column address signal) of the LM flag is prohibited as a matter of course.

With this operation, first and second latch circuits LA-1 and LA-2 in data latch circuit 13-4 corresponding to the redundancy area latch “0”. In this state, when write operation is executed, the threshold distribution of the LM flag shifts from Er to B as shown in FIG. 6.

(3) Summary

According to the second embodiment, the LM flag redundancy circuit which stores the bad information of the LM flag and the redundancy column (replacement destination address) storing the LM flag is newly provided in the data transfer control circuit. The LM flag redundancy circuit is activated in LM-dump. If a column storing the LM flag is a bad column, the LM flag redundancy circuit performs access by using the redundancy column (replacement destination address) instead of the address (bad column) of the LM flag.

This makes it possible to forcefully change the value of the lower data of the LM flag from “1” to “0” in the data latch circuit corresponding to the redundancy area. Not all the data of bad columns, therefore, need to be transferred between the data latch circuit corresponding to the redundancy area and that in the bad column data hold circuit, thereby shortening the write time.

8. Third Embodiment

In the third embodiment, an LM flag redundancy circuit (LMRD) which stores the bad information of an LM flag and a redundancy column (replacement destination address) storing the LM flag is newly provided in a bad column data hold circuit.

The LM flag redundancy circuit is activated in LM-dump. If a column storing the LM flag is a bad column, the LM flag redundancy circuit performs access using the redundancy column (replacement destination address) storing the LM flag. Whether the column storing the LM flag is a bad column is determined based on the bad information of the LM flag.

This makes it possible to forcefully change the value of the lower data of the LM flag from “1” to “0” in a data latch circuit corresponding to a redundancy area. Not all the data of bad columns, therefore, need to be transferred between the data latch circuit corresponding to the redundancy area and that in the bad column data hold circuit, thereby shortening the write time.

(1) Circuit Arrangement

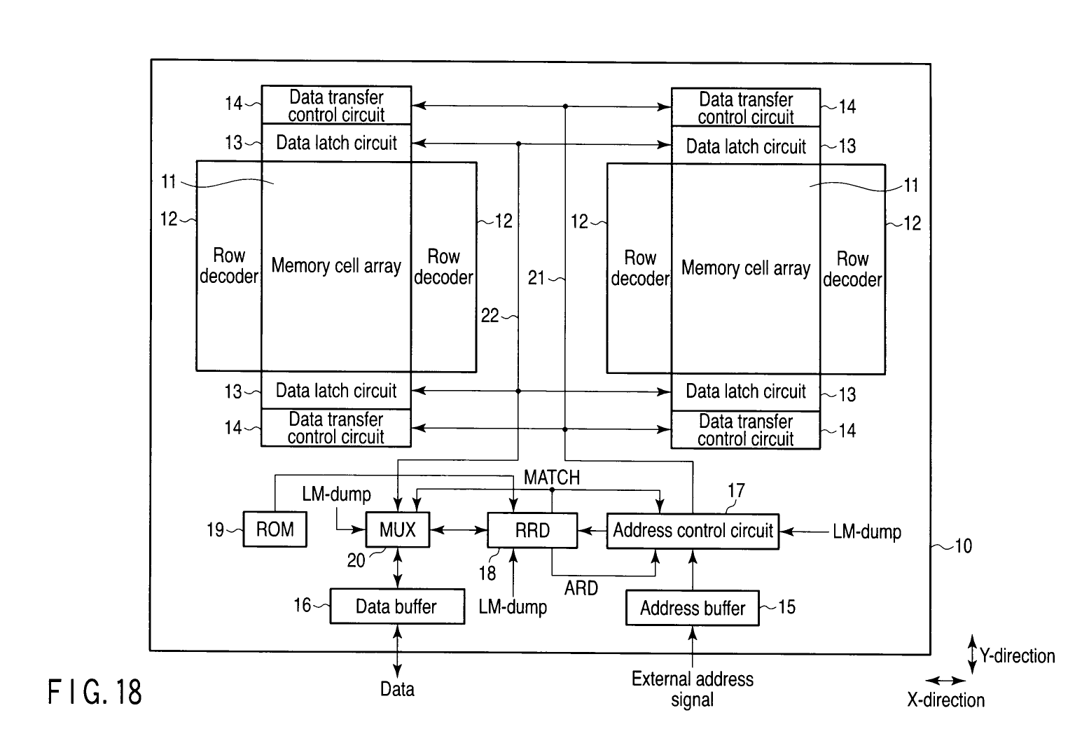

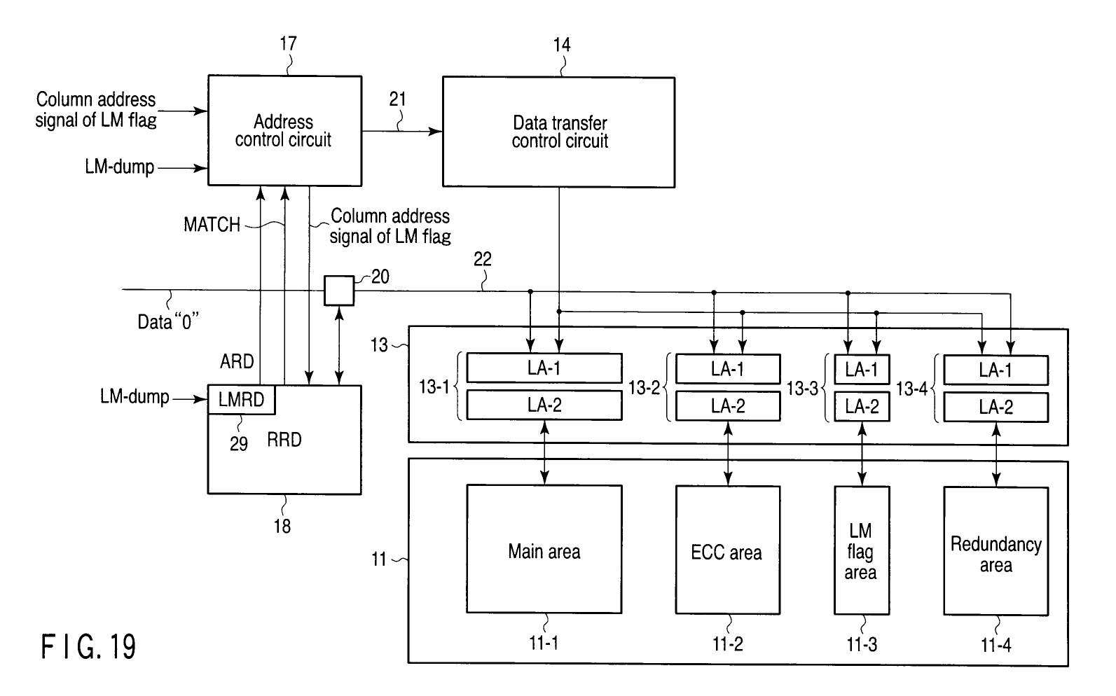

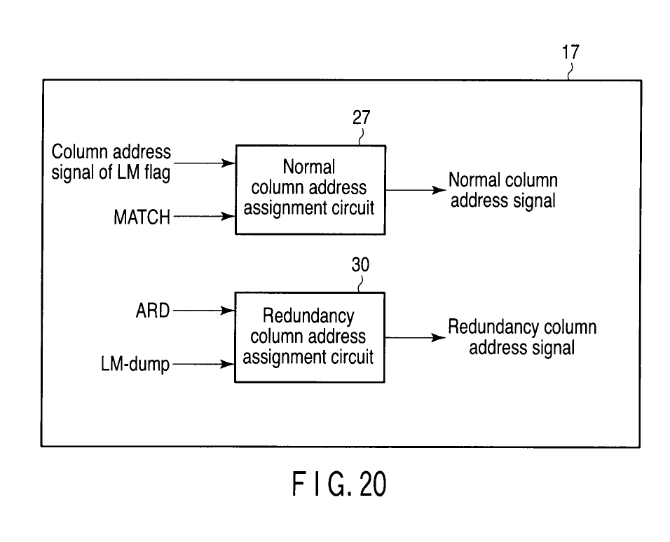

FIGS. 18, 19, and 20 show the circuit arrangement of a multi-level NAND flash memory according to the third embodiment.

Memory cell array 11, row decoder 12, data latch circuit 13, data transfer control circuit 14, address buffer 15, and data buffer 16 in multi-level NAND flash memory 10 have already been explained in detail above for FIGS. 1 and 5, and a description thereof will be omitted.

An external address signal is input to address control circuit 17 via address buffer 15. Address control circuit 17 supplies an external column address signal to data transfer control circuit 14 via address bus 21, and also provides it to bad column data hold circuit (RRD) 18.

The bad column data hold circuit 18 has a function of temporarily holding the data of bad columns in read/write operation. Whether data is that of a bad column is determined by comparing the column address signal from address control circuit 17 with a bad column address signal stored in ROM 19.

Bad column data hold circuit 18 has the circuit arrangement shown in FIGS. 3 and 10.

Details of the circuit arrangement have already been explained in detail above for FIGS. 3 and 10, and a description thereof will be omitted.

Switch circuit (MUX) 20 electrically connects two of data latch circuit 13, data buffer 16, and bad column data hold circuit 18 with each other. Data are transferred between the two circuits electrically connected with each other via data bus 22.

In read/write operation, if an external address signal from outside multi-level NAND flash memory (e.g., a chip) 10 or an address signal (e.g., the address of the LM flag) stored in address control circuit 17 selects a bad column, bad column data hold circuit 18 outputs match signal MATCH.

Match signal MATCH is input to address control circuit 17 and switch circuit 20. Upon reception of match signal MATCH, address control circuit 17 prohibits access to the bad column, i.e., transfer of the external address signal to data transfer control circuit 14.

Upon reception of match signal MATCH in read operation, switch circuit 20 electrically connects data buffer 16 with bad column data hold circuit 18, and reads data from bad column data hold circuit 18.

Upon reception of match signal MATCH in write operation, switch circuit 20 electrically connects data buffer 16 with bad column data hold circuit 18, and writes data in bad column data hold circuit 18.

Upon reception of control signal LM-dump, LM flag redundancy circuit 29 in bad column data hold circuit 18 is activated. If a column storing the LM flag is a bad column, LM flag redundancy circuit 29 generates address (replacement destination address) ARD of a redundancy column storing the LM flag.

Whether the column storing the LM flag is a bad column is determined by comparing the externally input column address signal of the LM flag with the bad information (column address signal) of the LM flag.

In addition to normal column address assignment circuit 27, address control circuit 17 has redundancy column address assignment circuit 28. If match signal MATCH is “H”, address control circuit 17 deactivates normal column address assignment circuit 27.

When control signal LM-dump representing that LM-dump is executed changes to “H”, address control circuit 17 activates redundancy column address assignment circuit 28.

Upon reception of control signal LM-dump, redundancy column address assignment circuit 28 transfers, to data transfer control circuit 14, address ARD of the redundancy column storing the LM flag output from bad column data hold circuit 18 regardless of whether the column address signal of the LM flag assigns a bad column.

Upon reception of control signal LM-dump, switch circuit 20 electrically connects data transfer control circuit 14 with data buffer 16, and transfers data “0” input in LM-dump to data latch circuit 13, regardless of match signal MATCH from bad column data hold circuit 18.

It is, therefore, possible to forcefully change the value of the lower data of the LM flag from “1” to “0” in the data latch circuit corresponding to the redundancy area in LM-dump.

This eliminates the need for transferring all the data of bad columns between the data latch circuit corresponding to the redundancy area and that in the bad column data hold circuit in order to only change the lower data of the LM flag, thereby shortening the write time.

(2) Write Procedure of Upper Data for LM Flag

A write procedure of upper data for the LM flag according to the third embodiment will be described.

Assume that a redundancy column stores the LM flag. Assume also that the write operation of the lower data (LM flag data) is complete, and the threshold distribution of the LM flag at this time is in state Er. Furthermore, when writing the upper data, the threshold distribution of the LM flag shifts from Er to B as shown in FIG. 6.

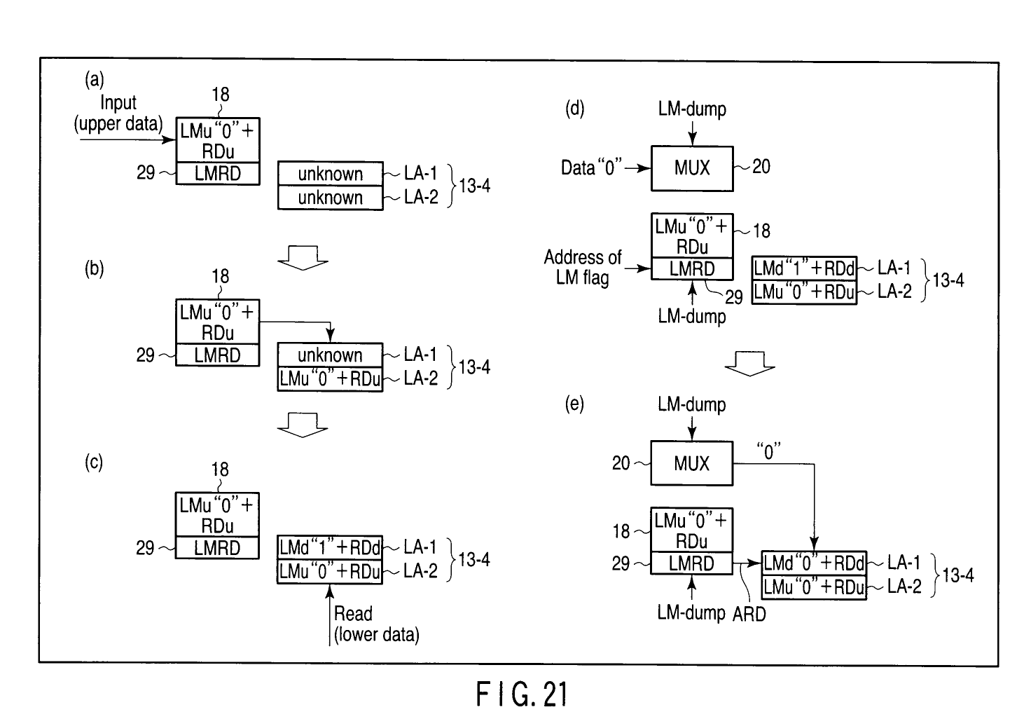

FIG. 21 shows a write procedure of upper data for the LM flag.

As shown in (a) of FIG. 21, when upper data for one page are input, the data of bad columns are input to bad column data hold circuit 18. That is, since a column storing the LM flag is a bad column, upper data (LM flag data LMu “0”) to be written in the LM flag is input to bad column data hold circuit 18.

Because there may exist bad columns other than the column storing the LM flag, upper data to be written in those columns are represented by RDu (“0” or “1”).

As described above, it is possible to readily determine whether data is that of a bad column, by comparing an external column address signal with a bad column address signal in bad column data hold circuit 18.

As shown in (b) of FIG. 21, data LMu “0”+RDu of the bad columns are collectively transferred from bad column data hold circuit 18 to second latch circuit LA-2 in data latch circuit 13-4 corresponding to the redundancy area.

This transfer operation is automatically executed by providing a means of sequentially incrementing a column address in the redundancy area from start to finish without using any external address signal as described in FIGS. 7 and 8.

As shown in (c) of FIG. 21, lower data is read from a memory cell in the redundancy area.

Assume that the lower data (LM flag data) read from the LM flag is represented by LMd “1”, and the lower data read from bad columns other than the column storing the LM flag are indicated by RDd (“0” or “1”).

These lower data are latched into first latch circuit LA-1 in data latch circuit 13-4.

Then, LM-dump is executed as shown in (d) and (e) of FIG. 21.

More specifically, as shown in (d) of FIG. 21, the address (external column address signal) of the LM flag is input to LM flag redundancy circuit (LMRD) 29 in bad column data hold circuit 18 via the address control circuit.

Upon reception of control signal LM-dump, LM flag redundancy circuit 29 is activated. If the column storing the LM flag is determined to be a bad column based on the bad information of the LM flag, LM flag redundancy circuit 29 generates address (replacement destination address) ARD of a redundancy column storing the LM flag.

As shown in (e) of FIG. 21, upon reception of control signal LM-dump, the address control circuit transfers address ARD of the redundancy column storing the LM flag to the data transfer control circuit regardless of whether the address of the LM flag assigns a bad column.

The redundancy column storing the LM flag is accessed based on redundancy column address ARD output from LM flag redundancy circuit 29.

Based on the received control signal LM-dump, switch circuit 20 transfers data “0” to first latch circuit LA-1 in data latch circuit 13-4 regardless of match signal MATCH from bad column data hold circuit 18.

Of lower data LMd “1”+RDd latched into first latch circuit LA-1 in data latch circuit 13-4, only lower data LMd “1” for the LM flag is forcefully changed to LMd “0”.

With this operation, first and second latch circuits LA-1 and LA-2 in data latch circuit 13-4 corresponding to the redundancy area latch “0”. In this state, when write operation is executed, the threshold distribution of the LM flag shifts from Er to B as shown in FIG. 6.

(3) Summary

According to the third embodiment, the LM flag redundancy circuit which stores the bad information of the LM flag and the redundancy column (replacement destination address) storing the LM flag is newly provided in the bad column data hold circuit. The LM flag redundancy circuit is activated in LM-dump. If a column storing the LM flag is a bad column, the LM flag redundancy circuit performs access by using the redundancy column (replacement destination address) instead of the address (bad column) of the LM flag.

This makes it possible to forcefully change the value of the lower data of the LM flag from “1” to “0” in the data latch circuit corresponding to the redundancy area. Not all the data of the bad columns, therefore, need to be transferred between the data latch circuit corresponding to the redundancy area and that in the bad column data hold circuit, thereby shortening the write time.

9. Conclusion

According to the embodiments, it is possible to execute write operation by the LM mode at a high speed.

The embodiments have great industrial merits with respect to file memories readable/writable at a high speed, mobile terminals capable of downloading at a high speed, portable players capable of downloading at a high speed, semiconductor memories for broadcast equipments, drive recorders, home video recorders, mass buffer memories for communication, semiconductor memories for security cameras, and the like.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi-level NAND flash memory comprising:
a memory cell array;
a data transfer control circuit arranged on one side of the memory cell array, and configured to control data transfer to the memory cell array;
a data latch circuit arranged between the memory cell array and the data transfer control circuit;
a bad column data hold circuit configured to temporarily hold data of a bad column in read/write operation;
a data buffer serving as an interface for data;
an address buffer serving as an interface for an address;
a switch circuit configured to transfer data between two of the data buffer, the data latch circuit, and the bad column data hold circuit; and
an address control circuit configured to transfer the address to the bad column data hold circuit, and to prohibit, if the address is determined to assign a bad column in the bad column data hold circuit, transfer operation of the address to the data transfer control circuit,
wherein a threshold distribution of a memory cell constituting the memory cell array is set to a first state or a second state in an ascending order of a threshold in a state in which lower data is written, and is set to a third state, a fourth state, a fifth state, or a sixth state in an ascending order of a threshold in a state in which lower data and upper data are written, and
the second state is different from the fourth state, the fifth state, and the sixth state,
wherein the memory cell array includes a main area storing main data, a flag area storing a flag for determining whether the main data contains only lower data or both lower data and upper data, and a redundancy area having a redundancy column,
wherein a threshold distribution of the flag is set to the first state in a state in which lower data is written, and is set to the fifth state in a state in which lower data and upper data are written, and
wherein when an address of the flag assigns a bad column, the data transfer control circuit and the address control circuit control a write operation of upper data in the flag by an operation of
transmitting the upper data of the flag from the bad column data hold circuit to the data latch circuit,
reading the lower data of the flag from a redundancy column storing the flag into the data latch circuit,
generating an address of a redundancy column storing the flag based on the address of the flag, and
forcefully inverting the lower data of the flag in the data latch circuit by using the address of the redundancy column storing the flag.

2. The memory according to claim 1,
wherein when the address of the flag assigns a bad column, the bad column data hold circuit outputs a match signal indicating an order of the redundancy column storing the flag in the redundancy area, and
wherein when forcefully inverting a value of the flag, the address control circuit transfers, to the data transfer control circuit as the address of the redundancy column storing the flag, a value obtained by adding an ordinal number of the redundancy column storing the flag to a first address of the redundancy column in the redundancy area.

3. The memory according to claim 1,
wherein the data transfer control circuit has a flag redundancy circuit which is activated when forcefully inverting the value of the flag,
wherein when forcefully inverting the value of the flag, the address control circuit transfers the address of the flag to the data transfer control circuit regardless of whether the address of the flag assigns a bad column, and
wherein the flag redundancy circuit generates an address of the redundancy column storing the flag.

4. The memory according to claim 1,
wherein the bad column data hold circuit has a flag redundancy circuit which is activated when forcefully inverting the value of the flag,
wherein the flag redundancy circuit generates, based on the address of the flag, an address of the redundancy column storing the flag, and
wherein when forcefully inverting the value of the flag, the address control circuit transfers the address of the redundancy column storing the flag to the data transfer control circuit regardless of whether the address of the flag assigns a bad column.

5. The memory according to claim 1,
wherein when forcefully inverting the value of the flag, the switch circuit transfers data for forcefully inverting the value of the flag to the data latch circuit regardless of whether the address of the flag assigns a bad column.

6. A method of writing data to a multi-level NAND flash memory comprising:
a memory cell array;
a data transfer control circuit arranged on one side of the memory cell array, and configured to control data transfer to the memory cell array;
a data latch circuit arranged between the memory cell array and the data transfer control circuit;
a bad column data hold circuit configured to temporarily hold data of a bad column in read/write operation;
a data buffer serving as an interface for data;
an address buffer serving as an interface for an address;
a switch circuit configured to transfer data between two of the data buffer, the data latch circuit, and the bad column data hold circuit; and
an address control circuit configured to transfer the address to the bad column data hold circuit, and to prohibit, if the address is determined to assign a bad column in the bad column data hold circuit, transfer operation of the address to the data transfer control circuit,
wherein a threshold distribution of a memory cell constituting the memory cell array is set to a first state or a second state in an ascending order of a threshold in a state in which lower data is written, and is set to a third state, a fourth state, a fifth state, or a sixth state in an ascending order of a threshold in a state in which lower data and upper data are written, and
the second state is different from the fourth state, the fifth state, and the sixth state,
wherein the memory cell array includes a main area storing main data, a flag area storing a flag for determining whether the main data contains only lower data or both lower data and upper data, and a redundancy area having a redundancy column,
wherein a threshold distribution of the flag is set to the first state in a state in which lower data is written, and is set to the fifth state in a state in which lower data and upper data are written, and
wherein when an address of the flag assigns a bad column, upper data is written in the flag after an operation of
transmitting the upper data of the flag from the bad column data hold circuit to the data latch circuit,
reading the lower data of the flag from a redundancy column storing the flag into the data latch circuit,
generating an address of a redundancy column storing the flag based on the address of the flag, and
forcefully inverting the lower data of the flag in the data latch circuit by using the address of the redundancy column storing the flag.

7. The method according to claim 6,
wherein when the address of the flag assigns a bad column, the bad column data hold circuit outputs a match signal indicating an order of the redundancy column storing the flag in the redundancy area, and
wherein when forcefully inverting a value of the flag, the address control circuit transfers, to the data transfer control circuit as the address of the redundancy column storing the flag, a value obtained by adding an ordinal number of the redundancy column storing the flag to a first address of the redundancy column in the redundancy area.

8. The method according to claim 6,
wherein the data transfer control circuit has a flag redundancy circuit which is activated when forcefully inverting the value of the flag,
wherein when forcefully inverting the value of the flag, the address control circuit transfers the address of the flag to the data transfer control circuit regardless of whether the address of the flag assigns a bad column, and
wherein the flag redundancy circuit generates an address of the redundancy column storing the flag.

9. The method according to claim 6,
wherein the bad column data hold circuit has a flag redundancy circuit which is activated when forcefully inverting the value of the flag,
wherein the flag redundancy circuit generates, based on the address of the flag, an address of the redundancy column storing the flag, and
wherein when forcefully inverting the value of the flag, the address control circuit transfers the address of the redundancy column storing the flag to the data transfer control circuit regardless of whether the address of the flag assigns a bad column.

10. The method according to claim 6,
wherein when forcefully inverting the value of the flag, the switch circuit transfers data for forcefully inverting the value of the flag to the data latch circuit regardless of whether the address of the flag assigns a bad column.

11. A multi-level NAND flash memory comprising:
a memory cell array;
a data transfer control circuit arranged on one side of the memory cell array, and configured to control data transfer to the memory cell array;
a data latch circuit arranged between the memory cell array and the data transfer control circuit;
a bad column data hold circuit configured to temporarily hold data of a bad column in read/write operation;
a data buffer serving as an interface for data;
an address buffer serving as an interface for an address;
a switch circuit configured to transfer data between two of the data buffer, the data latch circuit, and the bad column data hold circuit; and
an address control circuit configured to transfer the address to the bad column data hold circuit, and to prohibit, if the address is determined to assign a bad column in the bad column data hold circuit, transfer operation of the address to the data transfer control circuit,
wherein the memory cell array includes a main area storing main data, a flag area storing a flag for determining whether the main data contains only lower data or both lower data and upper data, and a redundancy area having a redundancy column, and
wherein when an address of the flag assigns a bad column, the data transfer control circuit and the address control circuit control a write operation of upper data in the flag by an operation of
transmitting the upper data of the flag from the bad column data hold circuit to the data latch circuit,
reading the lower data of the flag from a redundancy column storing the flag into the data latch circuit,
generating an address of a redundancy column storing the flag based on the address of the flag, and
forcefully inverting the lower data of the flag in the data latch circuit by using the address of the redundancy column storing the flag.

12. The memory according to claim 11,
wherein when the address of the flag assigns a bad column, the bad column data hold circuit outputs a match signal indicating an order of the redundancy column storing the flag in the redundancy area, and
wherein when forcefully inverting a value of the flag, the address control circuit transfers, to the data transfer control circuit as the address of the redundancy column storing the flag, a value obtained by adding an ordinal number of the redundancy column storing the flag to a first address of the redundancy column in the redundancy area.

13. The memory according to claim 11,
wherein the data transfer control circuit has a flag redundancy circuit which is activated when forcefully inverting the value of the flag,
wherein when forcefully inverting the value of the flag, the address control circuit transfers the address of the flag to the data transfer control circuit regardless of whether the address of the flag assigns a bad column, and
wherein the flag redundancy circuit generates an address of the redundancy column storing the flag.

14. The memory according to claim 11,
wherein the bad column data hold circuit has a flag redundancy circuit which is activated when forcefully inverting the value of the flag,
wherein the flag redundancy circuit generates, based on the address of the flag, an address of the redundancy column storing the flag, and
wherein when forcefully inverting the value of the flag, the address control circuit transfers the address of the redundancy column storing the flag to the data transfer control circuit regardless of whether the address of the flag assigns a bad column.

15. The memory according to claim 11,
wherein when forcefully inverting the value of the flag, the switch circuit transfers data for forcefully inverting the value of the flag to the data latch circuit regardless of whether the address of the flag assigns a bad column.
